(19) United States
(12) Patent Application Publication
(10) Pub. No.: US 2025/0024593 A1
(43) Pub. Date: Jan. 16, 2025

(54) APPARATUS AND SYSTEMS TO RETAIN A PRINTED CIRCUIT BOARD BETWEEN MOUNTING PLATES

(71) Applicants: Phil Geng, Washougal, WA (US); Vishnu Prasadh Sugumar, Santa Clara, CA (US); Prabhakar Subrahmanyam, San Jose, CA (US); Zhiming Li, Shanghai (CN); Hao Zhou, Shanghai (CN); Ashish Gupta, Portland, OR (US); Sanjoy Saha, Portland, OR (US); Ralph V. Miele, Hillsboro, OR (US); David Shia, Portland, OR (US)

(72) Inventors: Phil Geng, Washougal, WA (US); Vishnu Prasadh Sugumar, Santa Clara, CA (US); Prabhakar Subrahmanyam, San Jose, CA (US); Zhiming Li, Shanghai (CN); Hao Zhou, Shanghai (CN); Ashish Gupta, Portland, OR (US); Sanjoy Saha, Portland, OR (US); Ralph V. Miele, Hillsboro, OR (US); David Shia, Portland, OR (US)

(21) Appl. No.: 18/900,242

(22) Filed: Sep. 27, 2024

Related U.S. Application Data
(63) Continuation of application No. PCT/CN2024/114455, filed on Aug. 26, 2024.

(30) Foreign Application Priority Data
Aug. 26, 2024 (WO) PCT/CN2024/114455

(51) Int. Cl. H05K 1/02

(52) U.S. Cl. CPC H05K 1/0271; H05K 2201/2036

(57) ABSTRACT

Systems, apparatus, articles of manufacture, and methods are disclosed to retain a printed circuit board between mounting plates. An example standoff comprises a first segment to be adjacent to a first surface of a metal plate and a second segment extending from the first segment toward a second surface of a printed circuit board (PCB), the standoff to maintain separation between the metal plate and the PCB. Also, the example standoff includes at least one of a biasing component to dampen motion between the metal plate and the PCB or a distal end on the second segment, the first segment having a first cross-sectional shape defining a first area, the distal end having a second cross-sectional shape defining a second area, the second area smaller than the first area.

### RELATED APPLICATIONS

This patent arises from International Application No. PCT/CN2024/114455, which was filed on Aug. 26, 2024. International Application No. PCT/CN2024/114455 is hereby incorporated herein by reference in its entirety. Priority to International Application No. PCT/CN2024/114455 is hereby claimed.

### BACKGROUND

A data center is a dedicated space (e.g., in one or more buildings) where computer systems and associated components (e.g., telecommunications systems, storage systems, etc.) are housed. Data centers can vary in size, power requirements, redundancy, and overall structure. For example, data centers can be implemented as an onsite data center (e.g., a data center on the premises of an enterprise), as a colocation data center (e.g., a data center that offers computational resources for rent), as a hyperscale data center (e.g., a relatively large data center that provides scalability for large scale workloads), and as an edge data center (e.g., a relatively small data center that is located near the edge of a network).

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 11.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17A illustrates an isometric view of an example Open Compute Project (OCP) accelerator module (OAM).

FIG. 17B is an exploded view of the example OAM of FIG. 17A.

FIG. 18A illustrates a cross-sectional view of a first example mounting plate, an example printed circuit board, and a second example mounting plate (collectively referred to as an example OAM card) mounted to an example system chassis.

FIG. 18B illustrates a cross-sectional view of the example OAM card when the fastener is mounted to the system chassis.

FIG. 19 illustrates a side view of the example OAM card of FIGS. 17A and 17B including the first standoff and the second standoff when assembled.

FIG. 20 illustrates a first example implementation of the first standoff of FIGS. 17A and 17B when assembled in the example OAM card.

FIG. 21A is a cross-sectional isometric view of the first standoff of FIG. 20.

FIG. 21B is an isometric view of the first standoff of FIG. 20.

FIG. 21C is a cross-sectional side view of the first standoff of FIG. 20.

FIG. 22 illustrates a cross-sectional view of a second example implementation of the first standoff of FIGS. 17A and 17B.

FIG. 23 illustrates a third example implementation of the first standoff of FIGS. 17A and 17B when assembled in the example OAM card.

FIG. 24A is an isometric view of the first standoff of FIG. 23.

FIG. 24B is a side view of the first standoff of FIG. 23.

FIG. 24C is another isometric view of the first standoff of FIG. 23.

FIG. 25A illustrates a cross-sectional view of a fourth example implementation of the first standoff of FIGS. 17A and 17B when assembled in the OAM card.

FIG. 25B illustrates an isometric view of the first standoff of FIG. 25A.

FIG. 26 illustrates a cross-sectional view of a fifth example implementation of the first standoff of FIGS. 17A and 17B.

FIG. 27 illustrates a cross-sectional view of a sixth example implementation of the first standoff of FIGS. 17A and 17B.

FIG. 28A illustrates a cross-sectional view of a seventh example implementation of the first standoff of FIGS. 17A and 17B.

FIG. 28B illustrates an isometric view of the first standoff of FIG. 28A.

FIG. 29 illustrates a cross-sectional view of an eighth example implementation of the first standoff of FIGS. 17A and 17B.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

A large data center (e.g., a colocation data center, a hyperscale data center, etc.) is an industrial-scale operation that can utilize as much electricity as a small town. Many data centers operate across the world to satisfy the processing requirements of the modern technological infrastructure. Accordingly, operating data centers requires a large amount of electricity. To improve the efficiency of operating a data center, industry leaders founded the Open Compute Project (OCP) to develop more energy efficient data center computing technologies. For example, making servers taller provides space for more effective heat sinks and allows fans to move more air with less energy. Also, by utilizing specially designed servers, energy consumption due to unnecessary expansion slots on the motherboard and unneeded components, such as a graphics card, can also be reduced.

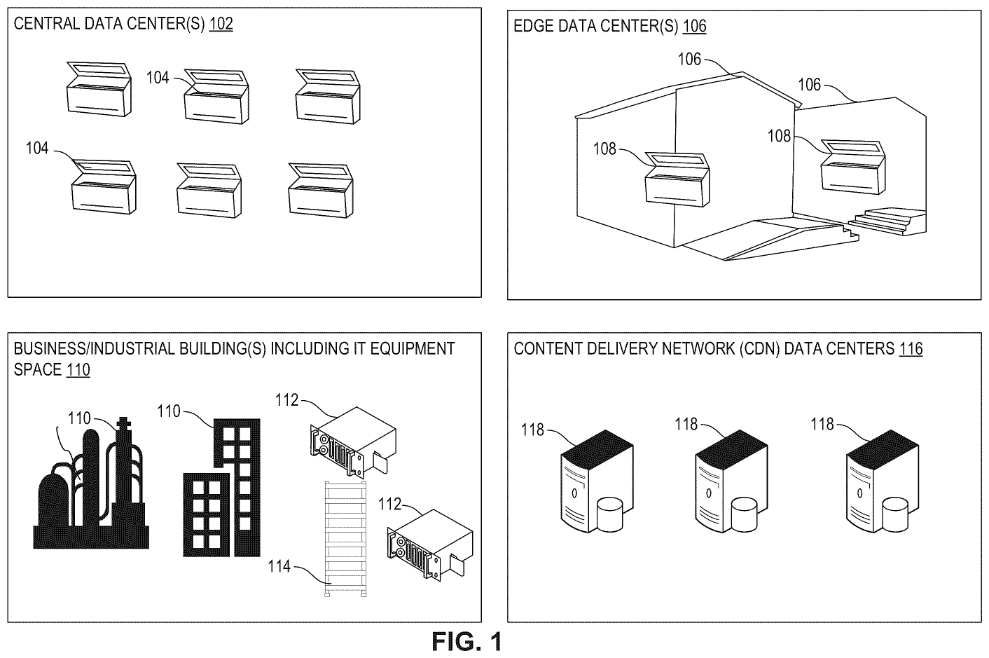

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., electromagnetic interference (EMI), vibration, extreme temperatures), and/or enable submergibility. Example housings may include power circuitry to provide power for stationary and/or portable implementations, such as alternating current (AC) power inputs, direct current (DC) power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

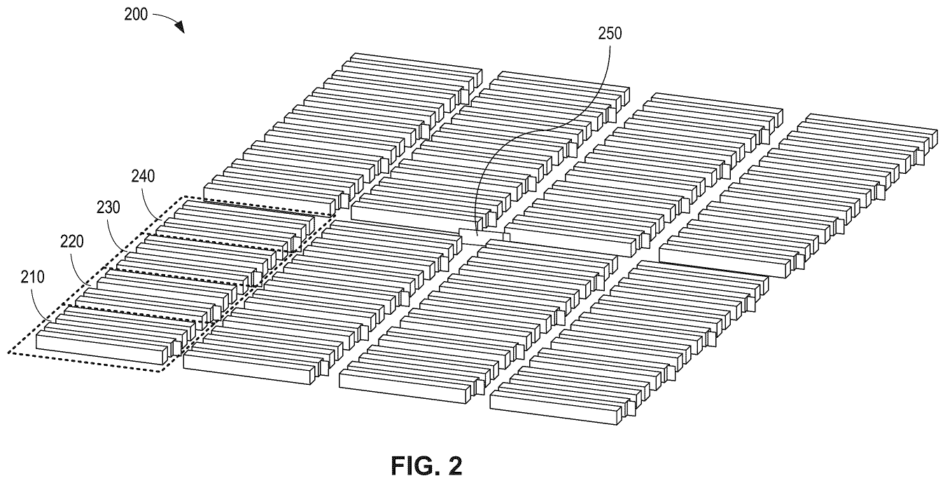

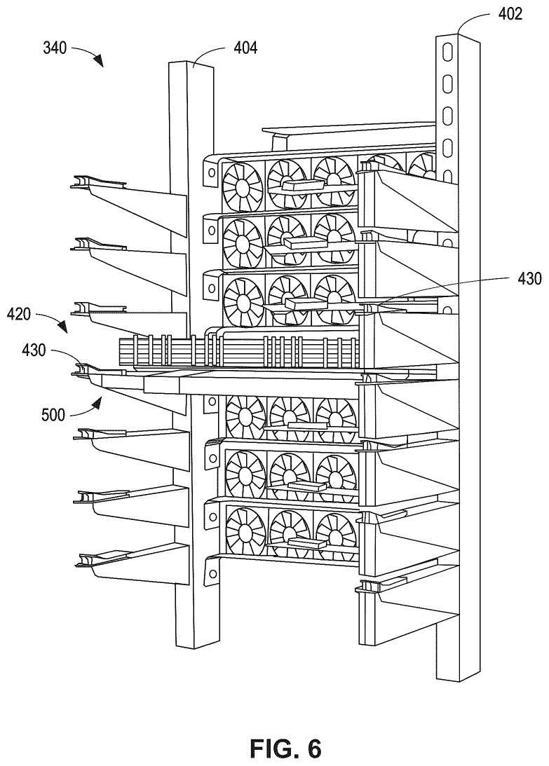

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is. in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein can be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose programmable circuitry) that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first programmable circuitry assigned to one managed node and second programmable circuitry of the same sled assigned to a different managed node).

A data center including disaggregated resources, such as the data center 200, can be used in a wide variety of contexts, such as enterprise, government, cloud service provider, and communications service provider (e.g., telecommunications providers), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage, and perhaps additional resources in a single chassis. For example, because a given sled will contain mostly resources of a same particular type, resources of that type can be upgraded independently of other resources. Additionally, because different resource types (programmable circuitry, storage, accelerators, etc.) typically have different refresh rates, greater resource utilization and reduced total cost of ownership may be achieved. For example, a data center operator can upgrade the programmable circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

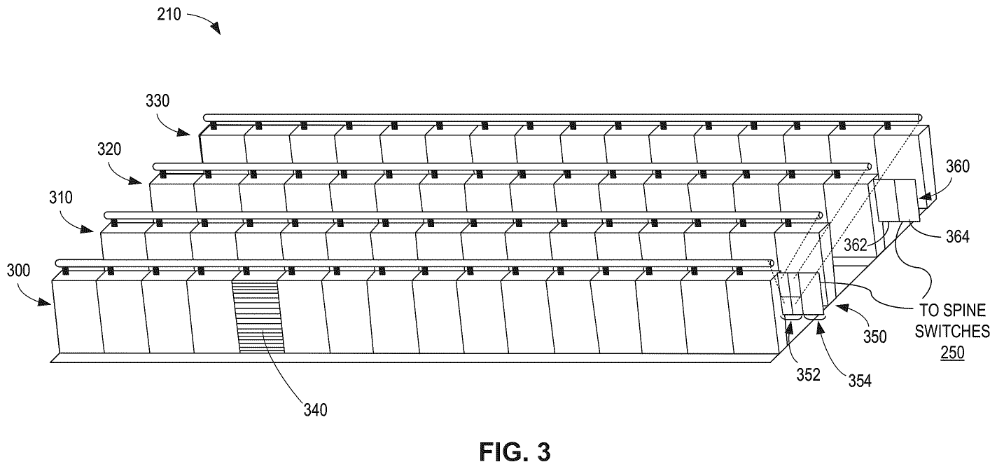

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., Peripheral Component Interconnect (PCI) Express (PCIe)) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, (e.g., the racks are equidistant from a center switch).

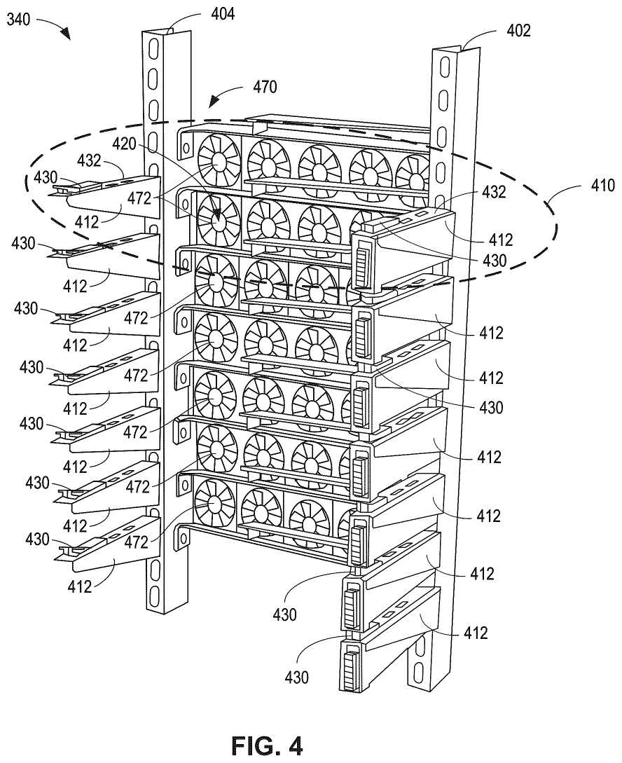

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., programmable circuitry, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

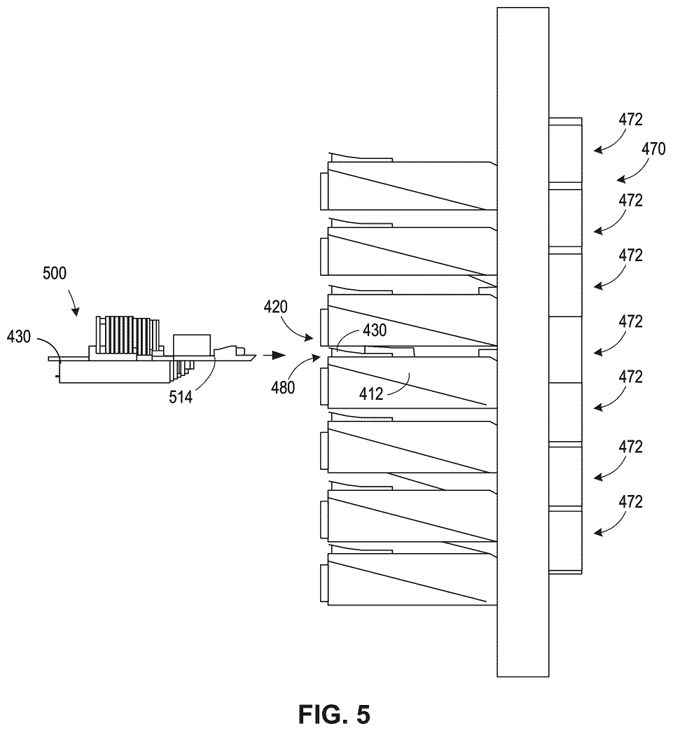

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (e.g., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level and may be controlled locally by components on the associated sled or remotely, such as by another sled or an orchestrator.

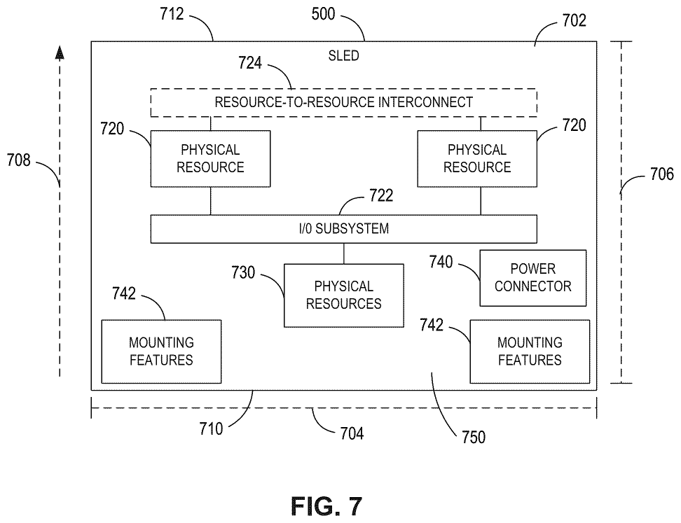

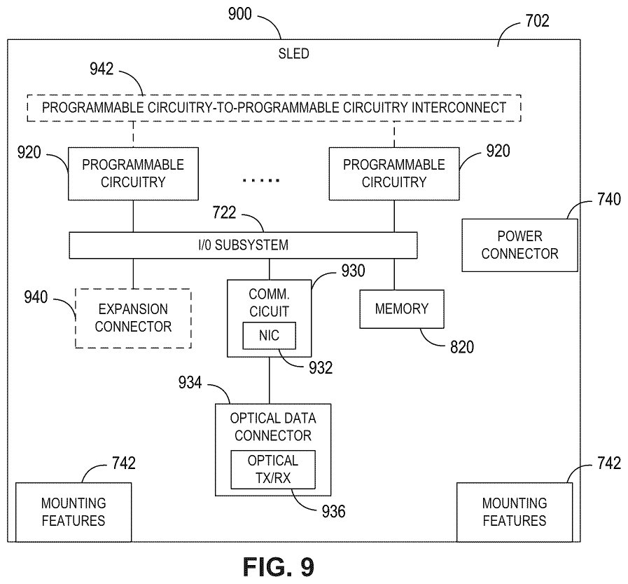

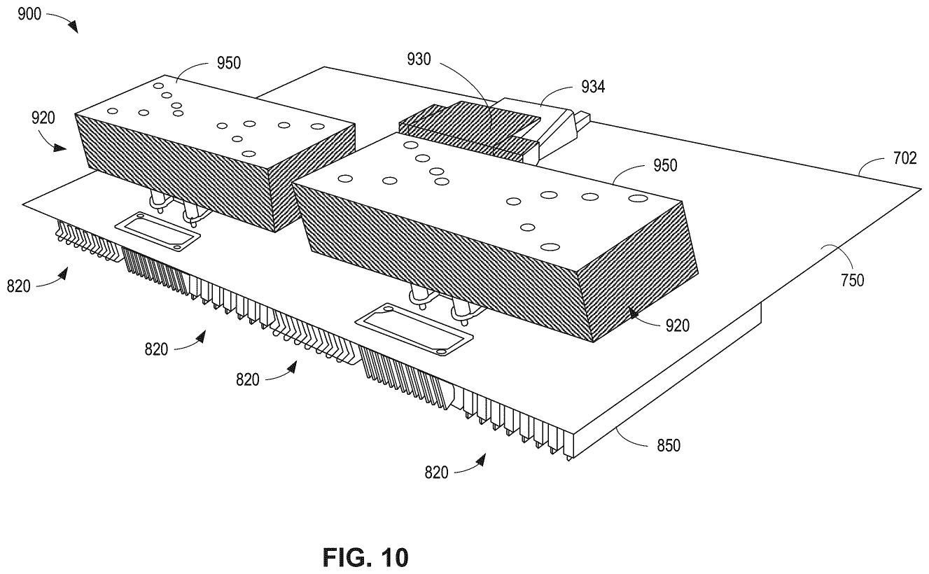

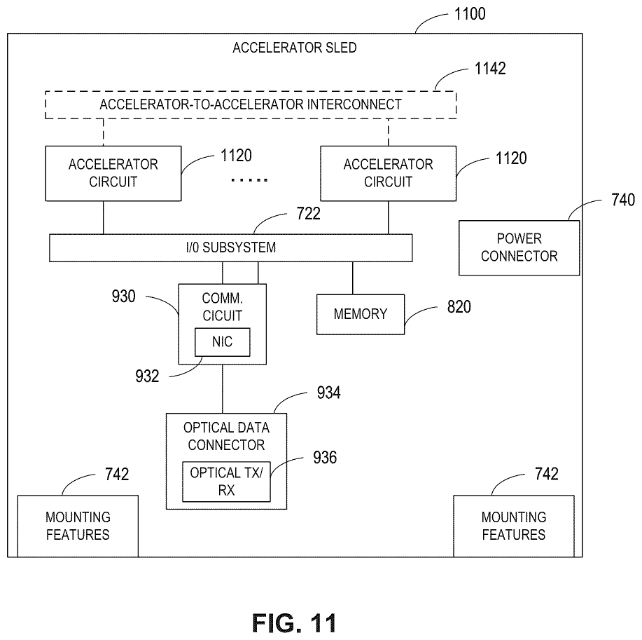

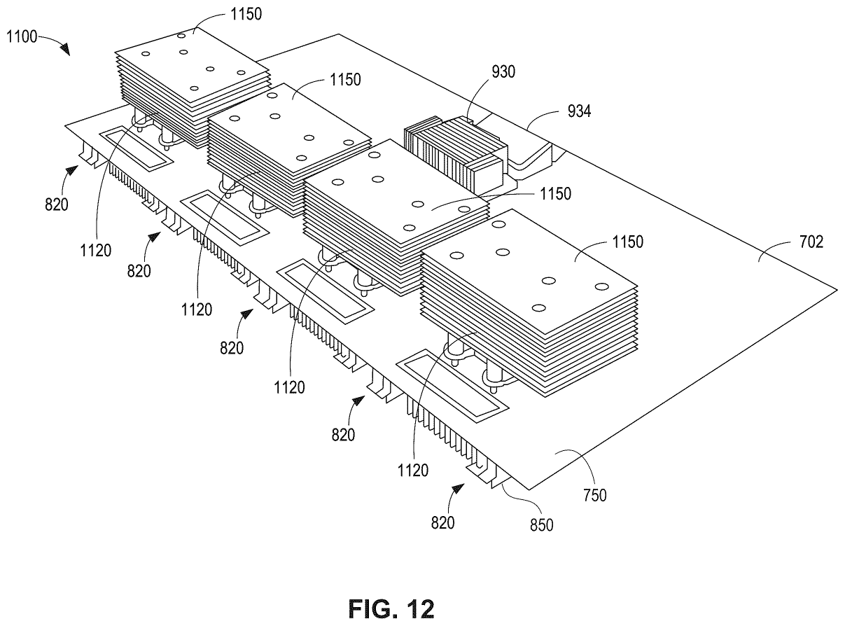

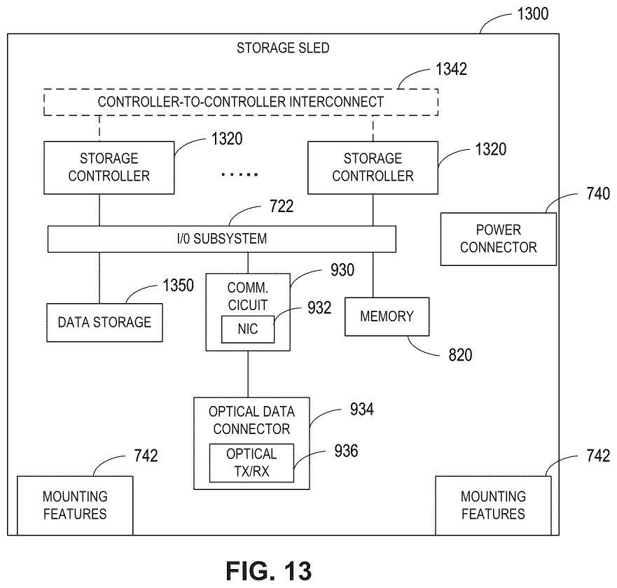

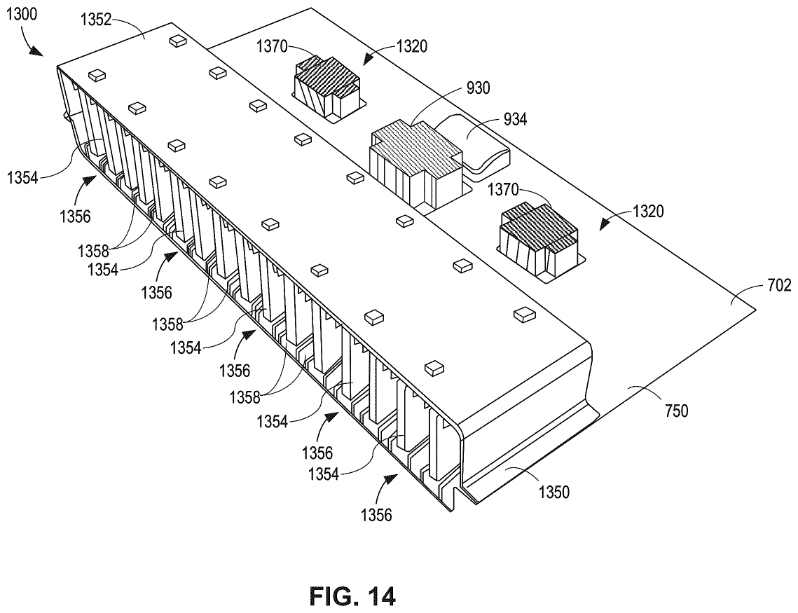

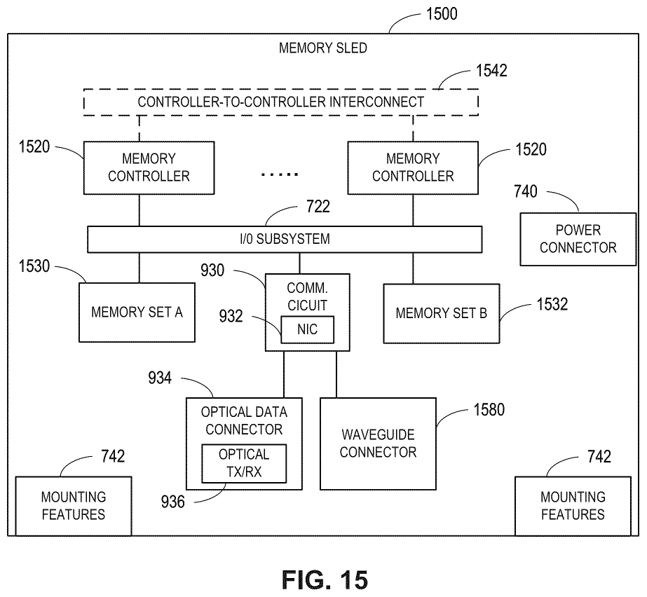

Referring now to FIG. 7, the sled 500, in the illustrative example, is configured to be mounted in a corresponding rack 340 of the data center 200 as discussed above. In some examples, a given sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (e.g., greater than a nominal heat sufficient enough to adversely impact the cooling of another electrical component), are mounted to the chassis-less circuit board substrate 702 linearly in-line with each other along the direction of the airflow path 708 (e.g., along a direction extending from the front edge 710 toward the rear edge 712 of the chassis-less circuit board substrate 702). The placement and/or structure of the features may be suitable adapted when the electrical component(s) are being cooled via liquid (e.g., one phase or two-phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of programmable circuitry, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processor circuitry in examples in which the sled 500 is implemented as a compute sled, as accelerator co-processor circuitry or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes a double data rate (DDR) data bus such as a DDR4 data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

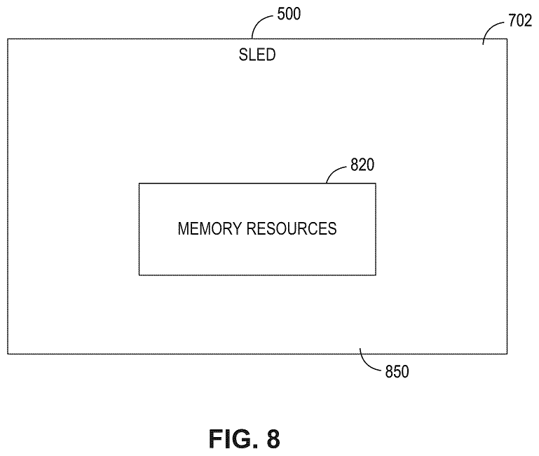

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (e.g., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of programmable circuitry 920 (see FIG. 9), and power is routed from the voltage regulators to the programmable circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 500 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random-access memory (DRAM), etc.) or non-volatile memory. Volatile memory may be a storage medium that requires power to maintain the state of data stored by the medium. Non-limiting examples of volatile memory may include various types of random-access memory (RAM), such as dynamic random-access memory (DRAM) or static random-access memory (SRAM). One particular type of DRAM that may be used in a memory module is synchronous dynamic random-access memory (SDRAM). In particular examples, DRAM of a memory component may comply with a standard promulgated by the Joint Electron Device Engineering Council (JEDEC) referred to as JESD, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NOT AND (NAND) or NOT OR (NOR) technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include programmable circuitry 920. Although only two blocks of programmable circuitry 920 are shown in FIG. 9, it should be appreciated that the compute sled 900 may include additional programmable circuits 920 in other examples. Illustratively, the programmable circuitry 920 corresponds to high-performance processor circuitry 920 and may be configured to operate at a relatively high-power rating. Although the high-performance programmable circuitry 920 generates additional heat operating at power ratings greater than typical processor circuitry (which operate at around 155-230 W), the enhanced thermal cooling characteristics of the chassis-less circuit board substrate 702 discussed above facilitate the higher power operation. For example, in the illustrative example, the programmable circuitry 920 is configured to operate at a power rating of at least 250 W. In some examples, the programmable circuitry 920 may be configured to operate at a power rating of at least 350 W.

In some examples, the compute sled 900 may also include a programmable circuitry-to-programmable circuitry interconnect 942. Similar to the resource-to-resource interconnect 724 of the sled 500 discussed above, the programmable circuitry-to-programmable circuitry interconnect 942 may be implemented as any type of communication interconnect capable of facilitating programmable circuitry-to-programmable circuitry interconnect 942 communications. In the illustrative example, the programmable circuitry-to-programmable circuitry interconnect 942 is implemented as a high-speed point-to-point interconnect (e.g., faster than the I/O subsystem 722). For example, the programmable circuitry-to-programmable circuitry interconnect 942 may be implemented as a Quick Path Interconnect (QPI), an UltraPath Interconnect (UPI), or other high-speed point-to-point interconnect dedicated to programmable circuitry-to-programmable circuitry communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processor circuits, or included on a multichip package that also contains one or more processor circuits. In some examples, the NIC 932 may include a local processor circuit (not shown) and/or a local memory (not shown) that are both local to the NIC 932. In such examples, the local processor circuit of the NIC 932 may be capable of performing one or more of the functions of the programmable circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the programmable circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processor circuitry, memory devices, storage devices, and/or accelerator circuits including, for example, field programmable gate arrays (FPGAs), application-specific integrated circuits (ASICs), security co-processor circuits, graphics processing units (GPUs), machine learning circuits, or other specialized processor circuits, controllers, devices, and/or circuits.

Referring now to FIG. 10, an illustrative example of the compute sled 900 is shown. As shown, the programmable circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor circuit socket), holders, or brackets. In some cases, some of the electrical components may be directly mounted to the chassis-less circuit board substrate 702 via soldering or similar techniques.

As discussed above, the separate programmable circuitry 920 and the communication circuit 930 are mounted to the top side 750 of the chassis-less circuit board substrate 702 such that no two heat-producing, electrical components shadow each other. In the illustrative example, the programmable circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the programmable circuitry 920 located on the top side 750 via the I/O subsystem 722. Because the chassis-less circuit board substrate 702 is implemented as a double-sided circuit board, the memory devices 820 and the programmable circuitry 920 may be communicatively coupled by one or more vias, connectors, or other mechanisms extending through the chassis-less circuit board substrate 702. Different programmable circuitry 920 (e.g., different processor circuitry) may be communicatively coupled to a different set of one or more memory devices 820 in some examples. Alternatively, in other examples, different programmable circuitry 920 (e.g., different processor circuitry) may be communicatively coupled to the same ones of the memory devices 820. In some examples, the memory devices 820 may be mounted to one or more memory mezzanines on the bottom side of the chassis-less circuit board substrate 702 and may interconnect with a corresponding programmable circuitry 920 through a ball-grid array.

Different programmable circuitry 920 (e.g., different processor circuitry) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340). the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the programmable circuitry heatsinks 950 include cooling fans attached thereto. That is, the heatsinks 950 may be fan-less heatsinks. In some examples, the heatsinks 950 mounted atop the programmable circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 applies to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor circuitry, co-processor circuitry, compute circuit, or other device capable of performing compute or processing operations. For example, the accelerator circuits 1120 may be implemented as, for example, FPGAs, ASICs, security co-processor circuitry, GPUs, neuromorphic processor units, quantum computers, machine learning circuits, or other specialized processor circuitry, controllers, devices, and/or circuits.

In some examples, the accelerator sled 1100 may also include an accelerator-to-accelerator interconnect 1142. Similar to the resource-to-resource interconnect 724 of the sled 500 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to programmable circuitry-to-programmable circuitry communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 500. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 applies to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of programmable circuitry, controller, or control circuit capable of controlling the storage and retrieval of data into the data storage 1350 based on requests received via the communication circuit 930. In the illustrative example, the storage controllers 1320 are implemented as relatively low-power programmable circuitry or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to programmable circuitry-to-programmable circuitry communications.

Referring now to FIG. 14, an illustrative example of the storage sled 1300 is shown. In the illustrative example, the data storage 1350 is implemented as, or otherwise includes a storage cage 1352 configured to house one or more solid state drives (SSDs) 1354. To do so, the storage cage 1352 includes a number of mounting slots 1356, which are configured to receive corresponding solid-state drives 1354. The mounting slots 1356 include a number of drive guides 1358 that cooperate to define an access opening of the corresponding mounting slot 1356. The storage cage 1352 is secured to the chassis-less circuit board substrate 702 such that the access openings face away from (e.g., toward the front of) the chassis-less circuit board substrate 702. As such, solid state drives 1354 are accessible while the storage sled 1300 is mounted in a corresponding rack 340. For example, a solid-state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid-state drives 1354 in other examples. Additionally, in the illustrative example, the solid state drives are mounted vertically in the storage cage 1352, but may be mounted in the storage cage 1352 in a different orientation in other examples. A given solid-state drive 1354 may be implemented as any type of data storage device capable of storing long term data. To do so, the solid-state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e g., a processor circuit socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530. 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of programmable circuitry, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to programmable circuitry-to-programmable circuitry communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets,” on a memory sled (e.g., the memory sled 1500). The chiplets may be interconnected (e.g., using Embedded Multi-Die Interconnect Bridge (EMIB) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (e.g., receive) lanes and 16 Tx (e.g., transmit) lanes. Different ones of the lanes, in the illustrative example, are either 16 gigahertz (GHz) or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

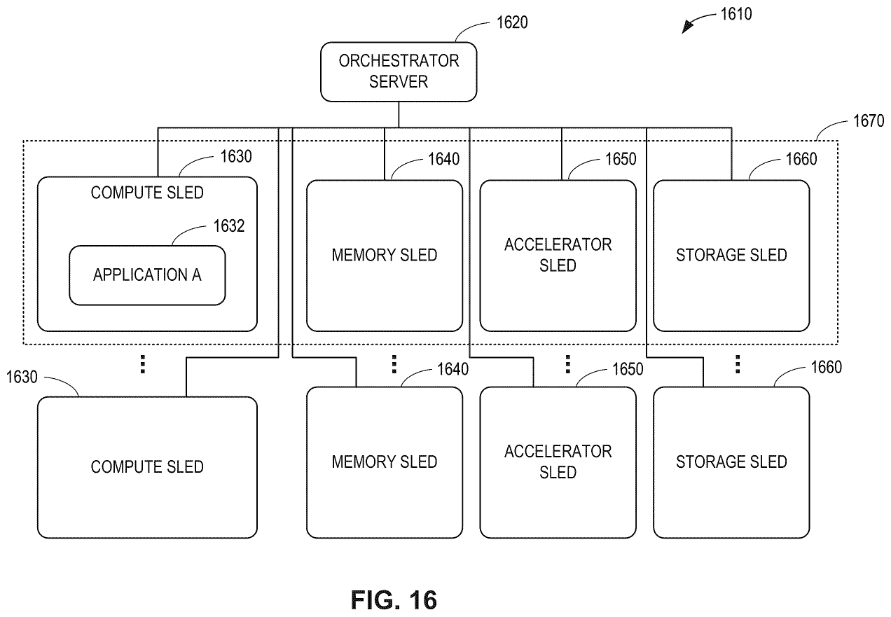

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., programmable circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1500), and storage sleds 1660 (e.g., similar to the storage sled 1300). One or more of the sleds 1630, 1640, 1650, 1660 may be grouped into a managed node 1670, such as by the orchestrator server 1620. to collectively perform a workload (e.g., an application 1632 executed in a virtual machine or in a container). The managed node 1670 may be implemented as an assembly of physical resources 720, such as programmable circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality-of-service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of beat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of programmable circuitry or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

As described above, the OCP was founded to develop more energy efficient data center computing technologies to improve the efficiency of operating a data center. Artificial intelligence (AI) is an evolving field that is placing increased demand on data centers. To keep up with the demand, many developers have produced accelerators for machine learning, deep learning, and high-performance computing. Example accelerators include GPUs, FPGAs, ASICs, infrastructure processing units (IPUs), neural processing units (NPUs), XPUs, among others. For example, an XPU may be implemented by a heterogeneous computing system including multiple types of programmable circuitry (e.g., one or more FPGAs, one or more central processor units (CPUs), one or more GPUs, one or more NPUs, one or more digital signal processors (DSPs), etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

To incorporate an accelerator to a server, the accelerator is generally implemented as an expansion card. For example, an expansion card is a printed circuit board (PCB) that can be inserted into an electrical connector or expansion slot on the motherboard of a computing system. However, expansion cards are implemented in a variety of shapes, with a range of thermal characteristics, wiring schematics, and unique sockets. Some standardized form factors for expansion cards exist, but these standardized form factors are not adapted to AI workloads. For example, expansion cards designed according to the PCIe card electromechanical (CEM) specification do not have sufficient bandwidth and interconnect flexibility for the data requirements of AI workloads. As such, members of the OCP developed a common form factor according to which different types of accelerators (e.g., GPUs, FPGAs, ASICs, IPUs, NPUs, XPUs, etc.) can be implemented as an expansion card. Accelerators implemented according to this common OCP form factor are referred to as OCP accelerator modules (OAMs).

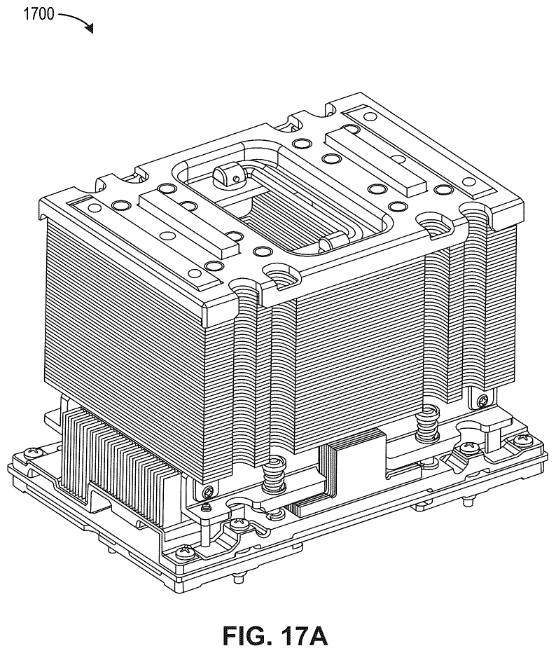

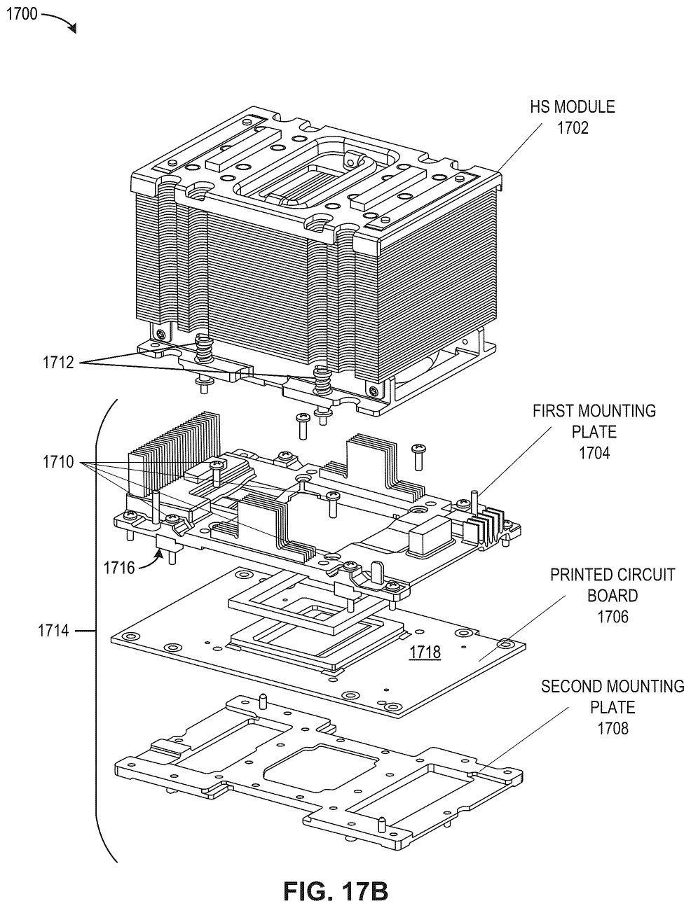

FIG. 17A illustrates an isometric view of an example OCP accelerator module (OAM) 1700. FIG. 17B is an exploded view of the example OAM 1700 of FIG. 17A. FIGS. 17A and 17B are referred to collectively herein as FIG. 17. In the example of FIG. 17, the OAM 1700 includes an example heat sink 1702, a first example mounting plate 1704, an example printed circuit board (PCB) 1706, and a second example mounting plate 1708. In the example of FIG. 17, the PCB 1706 is housed between the first mounting plate 1704 and the second mounting plate 1708. For example, the first mounting plate 1704, the PCB 1706, and the second mounting plate 1708 are coupled together by first example fasteners 1710. Also, for example, the heat sink 1702 is coupled to the first mounting plate 1704 by second example fasteners 1712.

In the illustrated example of FIG. 17, the first fasteners 1710 and the second fasteners 1712 are implemented by screws (e.g., threaded fasteners). In the example of FIG. 17, a washer may be implemented with one or more of at least one of the first fasteners 1710 or at least one of the second fasteners 1712. In additional or alternative examples, at least one of the first fasteners 1710 is implemented by a bolt or any other type of fastener. Also or alternatively, at least one of the second fasteners 1712 is implemented by a bolt or any other type of fastener. In some examples, one or more of the first mounting plate 1704, the PCB 1706, or the second mounting plate 1708 are coupled together by crimping, welding, soldering, brazing, taping, gluing, cementing, or by another adhesive.

In the illustrated example of FIG. 17, when the OAM 1700 is assembled, the first mounting plate 1704, the PCB 1706, and the second mounting plate 1708 are coupled together and referred to as an example OAM card 1714. For example, the first mounting plate 1704, the PCB 1706, and the second mounting plate 1708 are coupled together with the first fasteners 1710, which retain the PCB 1706 between the first mounting plate 1704 and the second mounting plate 1708. In the example of FIG. 17, the first fasteners 1710 extend through one or more of the first mounting plate 1704, the PCB 1706, or the second mounting plate 1708.

In the illustrated example of FIG. 17, some of the first fasteners 1710 extend through mounting holes in the first mounting plate 1704, the PCB 1706, and the second mounting plate 1708 and are received by respective threaded mounting holes in a chassis or base plate. Also, in the example of FIG. 17, some of the first fasteners 1710 extend through mounting holes in the first mounting plate 1704 and the PCB 1706 and are received by respective threaded mounting holes in the second mounting plate 1708.

In the illustrated example of FIG. 17. the first mounting plate 1704 and the second mounting plate 1708 are load-bearing components. For example, a compressive load exerted by the first fasteners 1710 is transferred onto the first mounting plate 1704 and the second mounting plate 1708 and around the PCB 1706. Also, when the OAM 1700 is assembled, the first mounting plate 1704 and the heat sink 1702 are coupled together via the second fasteners 1712. In the example of FIG. 17, the second fasteners 1712 retain the heat sink 1702 to the first mounting plate 1704. In the example of FIG. 17, the second fasteners 1712 extend through mounting holes in the heat sink 1702 and are received by respective threaded mounting holes in the first mounting plate 1704.

In the realm of hardware design, particularly within the context of OAM cards, the utilization of physical space (e.g., real estate) is a critical consideration. The consideration of physical space is accentuated by the spatial constraints of OAM cards. For example, in an OAM card some electrical components are positioned in proximal adjacency to PCB mounting apertures (e.g., openings, through holes, etc.). The close proximity of electrical components to PCB mounting apertures presents a challenge, potentially precipitating (e.g., resulting in) detrimental consequences such as mechanical stress concentration which can cause failures associated with surface mount technology (SMT) components.

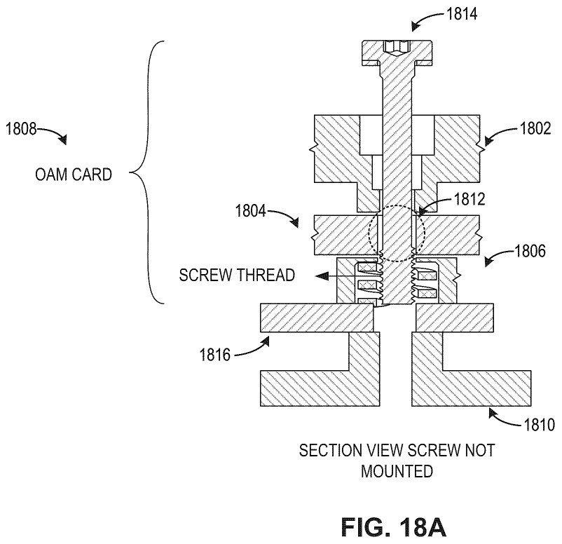

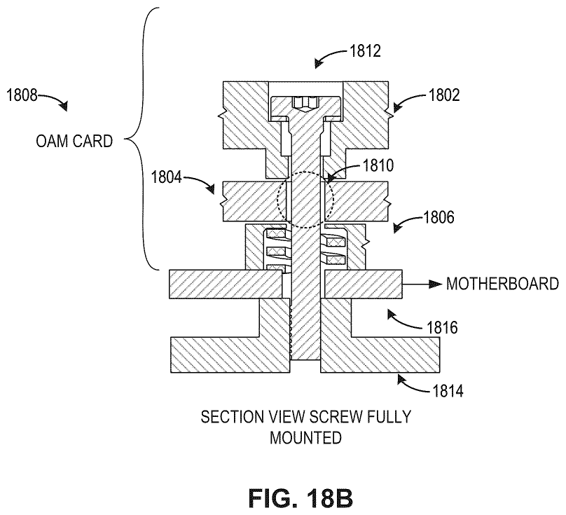

FIG. 18A illustrates a cross-sectional view of a first example mounting plate 1802, an example printed circuit board (PCB) 1804, and a second example mounting plate 1806 (collectively referred to as an example OAM card 1808) mounted to an example system chassis 1810. In the example of FIG. 18A, the PCB 1804 includes an example mounting hole 1812. As illustrated in FIG. 18A, the mounting hole 1812 can receive an example fastener 1814 that can be used to attached the OAM card 1808 to the system chassis 1810 (e.g., a base plate, a stiffener, etc.) through an example motherboard 1816 (e.g., a Unified Base Board (UBB)). FIG. 18A illustrates the fastener 1814 when not mounted to the system chassis 1810. FIG. 18B illustrates a cross-sectional view of the example OAM card 1808 when the fastener 1814 is mounted to the system chassis 1810. The involvement of the system chassis 1810 increases the risk of failure of the PCB 1804 and/or electrical components (e.g., SMT components) mounted thereto in an area near the mounting hole 1812, especially under shock and vibration loads.

As described above, OAM cards are inherently space-constrained, often resulting in the placement of components in close proximity to PCB mounting holes (e.g., the mounting hole 1812). When standoffs are positioned too close to (e.g., within a threshold distance of) an SMT component, the risk of a short or interference increases. Additionally, the rigid attachment of PCBs through mounting holes can introduce localized stress concentrations around mounting holes (e.g., during shock, vibration, and thermal cycling). In some examples, even a micro via in a top layer of a PCB can mechanically fail. Additionally, due to the relatively weak solder joints of SMT components (e.g., as compared to other mounting technologies), SMT components are particularly susceptible to damage from localized stresses.

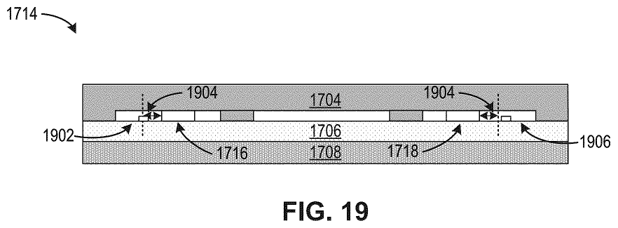

Returning to FIG. 17, as described above, the OAM card 1714 includes the first mounting plate 1704 (e.g., a top plate) and the second mounting plate 1708 (e.g., a back plate) that sandwich (e.g., are placed above and below, respectively) the PCB 1706. In this manner, the first mounting plate 1704 and/or the second mounting plate 1708 significantly mitigate overall bending strain on the PCB 1706. Additionally, the OAM card 1714 advantageously includes a first example standoff 1716 and a second example standoff 1718 between the first mounting plate 1704 and the PCB 1706. For example, FIG. 19 illustrates a side view of the example OAM card 1714 of FIG. 17 including the first standoff 1716 and the second standoff 1718 when assembled.

In the illustrated example of FIG. 19, the first standoff 1716 is positioned over an opening (e.g., a mounting hole) in the PCB 1706 that poses a high risk of localized stress. For example, the PCB 1706 includes an opening with at least a threshold number of components (e.g., a first example component 1902) around the opening. Additionally or alternatively, the PCB 1706 includes an opening with one or more components (e.g., the first component 1902) within an example threshold distance 1906 of the opening. In the example of FIG. 19, the threshold distance 1904 corresponds to a distance from a standoff that would cause a component (and/or solder associated with the component) to be damaged by stress imparted on the component (and/or the solder) as a result of loading on the standoff. Additionally or alternatively, the threshold distance 1904 corresponds to a difference between a first radius of an outermost perimeter of a standoff and a second radius of a perimeter of an opening above which the standoff is positioned. As such, if an opening is within the threshold distance 1904 of a component (and/or solder associated with the component), the component (and/or the solder) could be damaged by stress imparted on the component (and/or the solder) as a result of loading on a standoff positioned over the opening. Advantageously, in examples disclosed herein, the first standoff 1716 is designed with at least one of a compliant structure (e.g., a spring, a resiliently compressible material, etc.) or different cross-sectional shapes at opposite ends (e.g., a first cross-sectional shape adjacent the first mounting plate 1704 and a second, different cross-sectional shape adjacent the PCB 1706). As such, the first standoff 1716 reduces failure of at least one of the PCB 1706 or a component (e.g., the first component 1902) within the threshold distance 1904 of the first standoff 1716 due to localized stress concentration.

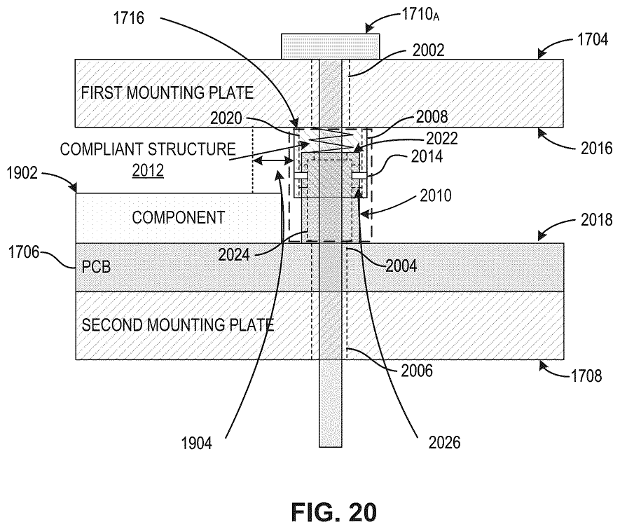

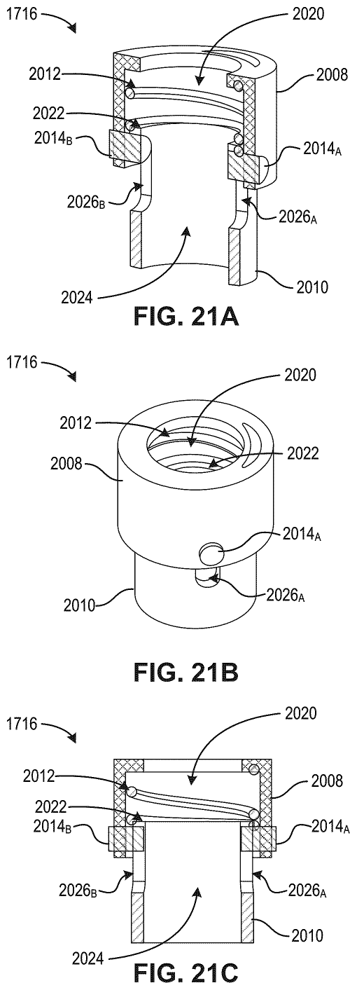

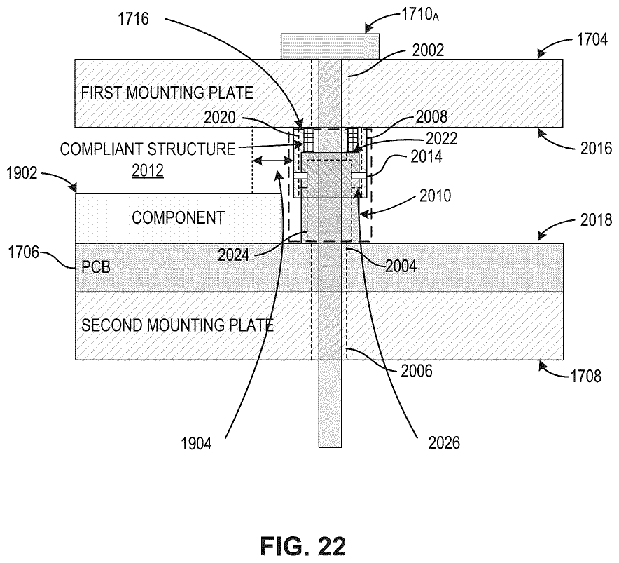

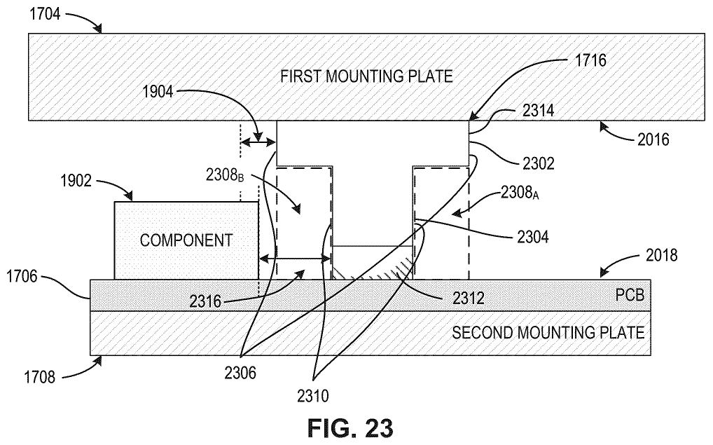

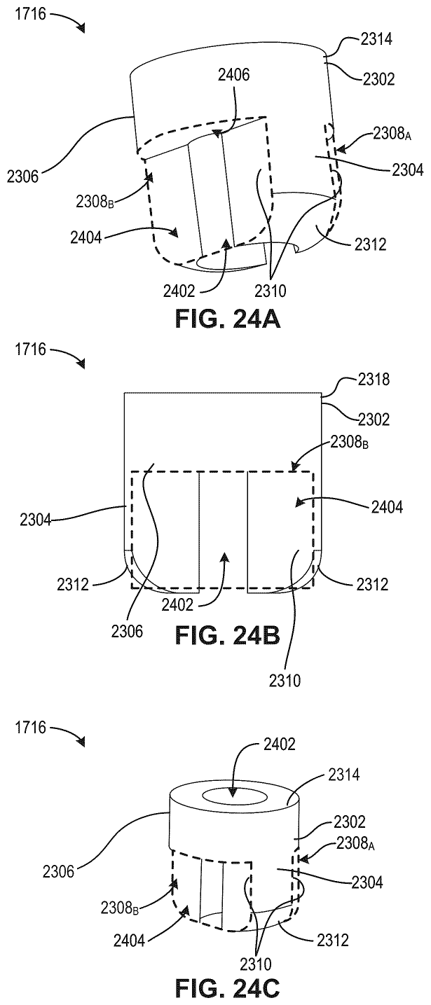

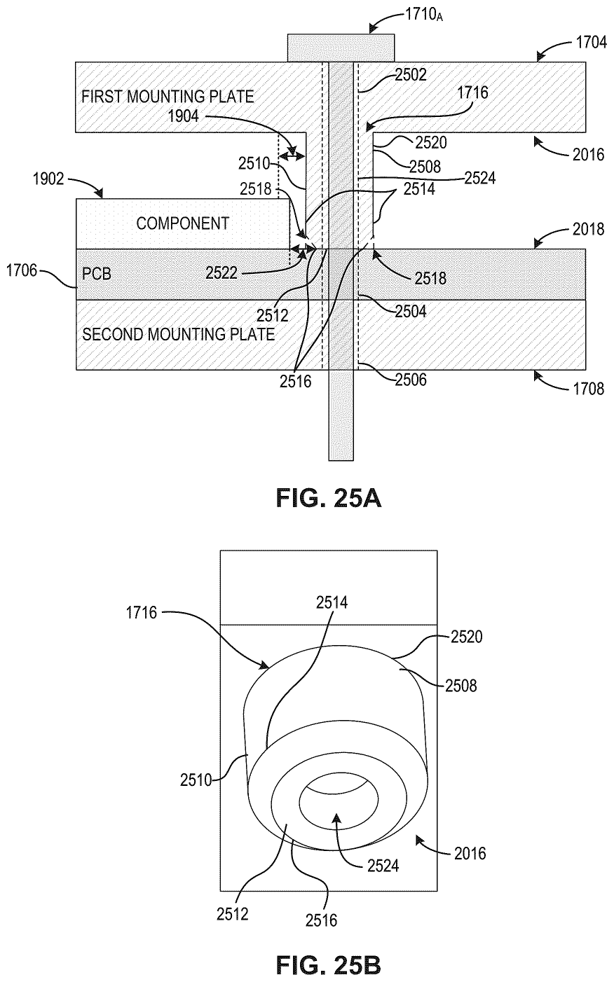

In examples disclosed herein, the first standoff 1716 includes an adjustable standoff with a compliant structure (e.g., a spring, a resiliently compliable material). FIG. 20 illustrates a cross-sectional view of a first example implementation of the first standoff 1716 of FIG. 17. FIGS. 21A-21C illustrate additional detail of the first standoff 1716 of FIG. 20. FIG. 22 illustrates a cross-sectional view of a second example implementation of the first standoff 1716 of FIG. 17. In some examples, the first standoff 1716 includes a clearance cutout such that the first standoff 1716 includes different cross-sectional shapes at opposite ends of the first standoff 1716. For example, the clearance cutout ensures that a component mounted to the surface of the PCB 1706 is at least a threshold distance from an inner perimeter of the first standoff 1716 even if the component is within the threshold distance of an outer perimeter of the first standoff 1716. FIG. 23 illustrates a third example implementation of the first standoff 1716 of FIG. 17. FIGS. 24A-24C illustrate additional detail of the first standoff 1716 of FIG. 23. FIGS. 25-29 illustrate additional or alternative implementations of the first standoff 1716 of FIG. 17.

In the illustrated example of FIG. 19, the second standoff 1718 is positioned over an opening (e.g., a mounting hole) in the PCB 1706 that poses a low risk of localized stress. For example, the PCB 1706 includes an opening with less than a threshold amount of components around the opening. Additionally or alternatively, the PCB 1706 includes an opening with components (e.g., a second example component 1906) that are more than the threshold distance 1904 from the opening. In some examples, the second standoff 1718 is positioned over an area of the PCB 1706 that does not include a mounting hole. In such examples, the second standoff 1718 may not include a passage through the second standoff 1718 (e.g., the second standoff 1718 does not serve as a passage for a fastener to mount the OAM card 1714 to a stiffener or base plate).

In examples disclosed herein, the second standoff 1718 is a fixed length standoff (e.g., is substantially rigid without a compliant structure). Additionally or alternatively, the second standoff 1718 has a uniform cross-sectional shape along a length of the second standoff 1718. For example, the second standoff 1718 has a uniform shape that is cylindrical, rectangular, or hexagonal. Also, for example, the second standoff 1718 is a solid material having a uniform shape and is used to separate the first mounting plate 1704 from the PCB 1706. In examples disclosed herein, the second standoff 1718 can be made of stainless steel, aluminum, brass, and/or nylon.

In some examples, the second standoff 1718 is coated with an electrically insulating material. In some examples, the second standoff 1718 includes threads on one end to fix the second standoff 1718 to the PCB 1706. Additionally or alternatively, in some examples, the second standoff 1718 is threadedly coupled to the first mounting plate 1704. In other examples, the second standoff 1718 is an integral extension of the first mounting plate 1704. As described above, in some examples, the first standoff 1716 has at least one of a different shape or includes a different material than the second standoff 1718. In examples disclosed herein, by (1) utilizing standoffs such as the first standoff 1716 over areas of the PCB 1706 that pose a high risk of localized stress and (2) utilizing standoffs such as the second standoff 1718 over areas of the PCB 1706 that pose a low risk of localized stress, examples disclosed herein reduce stress concentration in the OAM card 1714.

FIG. 20 illustrates a first example implementation of the first standoff 1716 of FIG. 17 when assembled in the example OAM card 1714. In the example of FIG. 20, a first example fastener 1710A of the first fasteners 1710 extends through a first example mounting hole 2002 of the first mounting plate 1704, the first standoff 1716, a second example mounting hole 2004 of the PCB 1706, and a third example mounting hole 2006 of the second mounting plate 1708. As such, the first standoff 1716 surrounds (e.g., is to surround) the first fastener 1710A. Also, in the example of FIG. 20, the first standoff 1716 includes a first example segment 2008, a second example segment 2010, an example compliant structure 2012, and one or more example pins 2014.

In the illustrated example of FIG. 20, the first segment 2008 is adjacent to and extends from a first example surface 2016 of the first mounting plate 1704 towards a second example surface 2018 of the second mounting plate 1708. For example, the first segment 2008 (e.g., a first portion) is an integral extension of the first mounting plate 1704 (e.g., a metal plate). In some examples, the first segment 2008 is distinct from and coupled to (e.g., threaded to, adhered to, welded to, etc.) the first mounting plate 1704. In the example of FIG. 20, the first segment 2008 is made of metal such as stainless steel, aluminum, and/or brass. In some examples, the first segment 2008 is coated with an electrically insulating material. In the example of FIG. 20, the first segment 2008 is cylindrical in shape (e.g., has a shape that is defined by a cylinder) and has a first example cavity 2020 defining an interior surface of the first segment 2008.

In the illustrated example of FIG. 20, the compliant structure 2012 is housed in the first cavity 2020 of the first segment 2008. In the example of FIG. 20, the compliant structure 2012 is held in compression between the first surface 2016 and a first example end 2022 of the second segment 2010. For example, the compliant structure 2012 is implemented by a spring that is held in compression between the first surface 2016 and the first end 2022. In additional or alternative examples, the compliant structure 2012 is implemented by at least one of rubber, silicone, foam, or a shape-memory alloy (SMA).

In the illustrated example of FIG. 20, the compliant structure 2012 is a biasing component that biases the second segment 2010 with respect to the first mounting plate 1704. For example, the compliant structure 2012 exerts a force on at least one of the second segment 2010 or the first mounting plate 1704 to hold the second segment 2010 in a first position relative to the first mounting plate 1704. Additionally or alternatively, the compliant structure 2012 exerts a force on at least one of the second segment 2010 or the first mounting plate 1704 to move the second segment 2010 (e.g., to urge the second segment 2010 to move) relative to the first mounting plate 1704.

In the illustrated example of FIG. 20, the second segment 2010 extends from the first segment 2008 toward the second surface 2018 of the PCB 1706. For example, the second segment 2010 (e.g., a second portion) extends from the first segment 2008 and rests on the second surface 2018 of the PCB 1706. In the example of FIG. 20, the second segment 2010 is made of metal such as stainless steel, aluminum, and/or brass. In some examples, the second segment 2010 is coated with an electrically insulating material. In the example of FIG. 20, the second segment 2010 is cylindrical in shape (e.g., has a shape that is defined by a cylinder) and has a second example cavity 2024 defining an interior surface of the second segment 2010. In other examples, one or both of the first segment 2008 and the second segments 2010 have a different cross-sectional shape

In the illustrated example of FIG. 20, the second segment 2010 has an exterior diameter that is smaller than an interior diameter of the first segment 2008. As such, the second segment 2010 can be inserted into the first cavity 2020 of the first segment 2008. Also, the interior diameter of the second segment is large enough to allow the first fastener 1710A to pass through the second segment 2010. In the example of FIG. 20, the second segment 2010 also includes example openings 2026 (e.g., slots) to receive respective ones of the one or more pins 2014.

In the illustrated example of FIG. 20, each of the one or more pins 2014 extends from the interior surface of the first segment 2008 into the first cavity 2020. For example, each of the one or more pins 2014 is embedded in the first segment 2008, extends from an exterior surface of the first segment 2008, through the first segment 2008, and into the first cavity 2020 As such, the second segment 2010 can move (e.g., is movable) relative to the first mounting plate 1704. For example, movement of the second segment 2010 is guided by the openings 2026 sliding along the one or more pins 2014. Thus, the length of the first standoff 1716 is adjustable (e.g., has an adjustable length) and the spring load (e.g., provided by the compliant structure 2012) allows the first standoff 1716 to absorb stress.

For example, when the OAM card 1714 is subjected to loading (e.g., shock loading, vibration loading, thermal cycling, etc.), the second segment 2010 can move as the compliant structure 2012 compresses under the load. In this manner, even though the first component 1902 is within the threshold distance 1904 of the first standoff 1716, the first standoff 1716 prevents localized stress from developing in the first component 1902, solder joints thereof, or the PCB 1706. As such, the first standoff 1716 reduces failure of at least one of the PCB 1706 or the first component 1902 in an area around the first standoff 1716 due to localized stress concentration.

FIG. 21A is a cross-sectional isometric view of the first standoff 1716 of FIG. 20. FIG. 21B is an isometric view of the first standoff 1716 of FIG. 20, and FIG. 21C is a cross-sectional side view of the first standoff 1716 of FIG. 20. As described above, the second segment 2010 includes the openings 2026 to receive respective ones of the one or more pins 2014. For example, as illustrated in FIGS. 21A-21C, the second segment 2010 includes a first example opening 2026A to receive a first example pin 2014A. The second segment 2010 also includes a second example opening 2026B to receive a second example pin 2014B. As illustrated in FIGS. 21A-21C, the second pin 2014B is positioned opposite to the first pin 2014A and the second opening 2026B is positioned opposite to the first opening 2026A.

As such, the one or more pins 2014 and the openings 2026 operate to restrict motion of the second segment 2010 relative to the first segment 2008 along an axis of the first standoff 1716. For example, when the OAM card 1714 is placed in compression under a load, the compliant structure 2012 allows the second segment 2010 to move relative to the first segment 2008, assuming the first segment 2008 is fixed (e.g., to the first mounting plate 1704). As such, the second segment 2010 can move axially within the first cavity 2020 and reduce the amount of stress imparted at the base of the second segment 2010. Accordingly, the first standoff 1716 applies a first amount of stress at a first location on the PCB 1706 that is less than a second amount of stress applied at a second location on the PCB 1706 by the second standoff 1718.

FIG. 22 illustrates a second example implementation of the first standoff 1716 of FIG. 17 when assembled in the OAM card 1714. In the example of FIG. 22, the compliant structure 2012 is implemented by a cylinder of rubber having an opening to allow the first fastener 1710A to pass through the compliant structure 2012. As described above, in additional or alternative examples, the compliant structure 2012 can be implemented by at least one of silicone, foam, or other resiliently compressible material, and/or an SMA.

FIG. 23 illustrates a third example implementation of the first standoff 1716 of FIG. 17 when assembled in the example OAM card 1714. In the example of FIG. 23, the first standoff 1716 includes a first example segment 2302 and a second example segment 2304. Also, in the example of FIG. 23, the first segment 2302 is adjacent to and extends from the first surface 2016 of the first mounting plate 1704 towards the second surface 2018 of the PCB 1706. For example, the first segment 2302 is an integral extension of the first mounting plate 1704 (e.g., a metal plate). In some examples, the first segment 2302 is distinct from and coupled to (e.g., threaded to, adhered to, welded to, etc.) the first mounting plate 1704.

In the illustrated example of FIG. 23. the second segment 2304 extends from the first segment 2302 towards the second surface 2018 of the PCB 1706. For example, the second segment 2304 is an integral extension of the first segment 2302. In some examples, the second segment 2304 is distinct from and coupled to (e.g., threaded to, adhered to, welded to, etc.) the first segment 2302. In the example of FIG. 23, the second segment 2304 extends from the first segment 2302 and rests on the second surface 2018 of the PCB 1706. In some examples, the second segment 2304 is coupled to the PCB 1706 (e.g., via threads, an adhesive, welding, etc.). In some examples, the first standoff 1716 (e.g., the first segment 2302 and the second segment 2304) is independent of the first mounting plate 1704 and is fixed between the first mounting plate 1704 and the PCB 1706 via compressive forces.

In the illustrated example of FIG. 23, the first segment 2302 and the second segment 2304 are made of metal such as stainless steel, aluminum, and/or brass. In some examples, the first segment 2302 and the second segment 2304 are coated with an electrically insulating material. In the example of FIG. 23, the first standoff 1716 is cylindrical in shape (e.g., has a shape that is defined by a cylinder) and the first segment 2302 defines an example exterior perimeter 2306 (e.g., outermost perimeter) of the first standoff 1716. In other examples, the exterior perimeter 2306 of the first standoff 1716 has a shape other than a cylinder. Also, the first standoff 1716 has a first example cavity 2308A and a second example cavity 2308B defining an example inner perimeter 2310 of the first standoff 1716.

In the illustrated example of FIG. 23, at least one of the first cavity 2308A or the second cavity 2308B is positioned towards (e.g., faces) the first component 1902 (and/or solder associated therewith). For example, the second cavity 2308B is positioned towards the first component 1902 (and/or solder associated therewith). Also, a retained portion of the first standoff 1716 (e.g., the second segment 2304) is positioned away from the first component 1902 (and/or solder associated therewith).

In the illustrated example of FIG. 23, the first segment 2302 has a first cross-sectional shape defining a first area and the second segment 2304 has a second cross-sectional shape defining a second area that is smaller than the first area As such, an example distal end 2312 of the first standoff 1716 is spaced apart from the first component 1902 (and/or solder associated therewith) by at least the threshold distance 1904 even if a first example end 2314 of the first standoff 1716 is within the threshold distance 1904 of the first component 1902 (and/or solder associated therewith). For example, the distal end 2312 is spaced apart from the first component 1902 in a direction normal to an exterior surface of the first standoff 1716.

In the illustrated example of FIG. 23, an example distance 2316 between the inner perimeter 2310 and the first component 1902 (and/or solder associated therewith) is greater than or equal to the threshold distance 1904. As such, the first standoff 1716 includes a clearance cutout (e.g., at least one of the first cavity 2308A or the second cavity 2308B) that ensures that the first component 1902 (and/or solder associated therewith) is far enough away from the portion of the first standoff 1716 that interfaces with the PCB 1706 to avoid problematic stress concentrations on the PCB 1706. Additionally, the distal end 2312 of the first standoff 1716 has filleted edges (e.g., at least one filleted edge) which distribute stress more evenly along the second surface 2018 of the PCB 1706. Accordingly, the first standoff 1716 applies a first amount of stress at a first location on the PCB 1706 that is less than a second amount of stress applied at a second location on the PCB 1706 by the second standoff 1718.

FIG. 24A is an isometric view of the first standoff 1716 of FIG. 23. FIG. 24B is a side view of the first standoff 1716 of FIG. 23, and FIG. 24C is another isometric view of the first standoff 1716 of FIG. 23. FIGS. 24A-24C are collectively referred to as FIG. 24. As illustrated in FIG. 24, the first standoff 1716 has an example through hole 2402 (e.g., a mounting hole) extending along an axial length of the first standoff 1716. Also, as illustrated in FIG. 24, the first cavity 2308A and the second cavity 2308B intersect the through hole 2402. In other examples, the first cavity 2308A and the second cavity 2308B do not intersect the through hole 2402.

In the illustrated example of FIG. 24, each of the first cavity 2308A and the second cavity 2308B is defined by a first example planar surface 2404 that is approximately parallel relative to an axial length of the first standoff 1716 and a second example planar surface 2406 that is approximately perpendicular to the axial length of the first standoff 1716. As used herein, approximately parallel is defined to mean exactly parallel or within five degrees of exactly parallel, and approximately perpendicular is defined to mean exactly perpendicular or within five degrees of exactly perpendicular. In other examples, the first planar surface 2404 and the second planar surface 2406 can be at any other suitable angle relative to the axial length of the first standoff 1716.

FIG. 25A illustrates a cross-sectional view of a fourth example implementation of the first standoff 1716 of FIG. 17 when assembled in the OAM card 1714. FIG. 25B illustrates an isometric view of the first standoff 1716 of FIG. 25A. FIGS. 25A and 25B are referred to collectively as FIG. 25. In the example of FIG. 25, the first fastener 1710A extends through a first example mounting hole 2502 of the first mounting plate 1704, the first standoff 1716, a second example mounting hole 2504 of the PCB 1706, and a third example mounting hole 2506 of the second mounting plate 1708. As such, the first standoff 1716 surrounds (e.g., is to surround) the first fastener 1710A. Also, in the example of FIG. 25, the first standoff 1716 includes a first example segment 2508 and a second example segment 2510.

In the illustrated example of FIG. 25, the first segment 2508 is adjacent to and extends from the first surface 2016 of the first mounting plate 1704 towards the second surface 2018 of the PCB 1706. For example, the first segment 2508 is an integral extension of the first mounting plate 1704 (e.g., a metal plate). In some examples, the first segment 2508 is distinct from and coupled to (e.g., threaded to, adhered to, welded to, etc.) the first mounting plate 1704.

In the illustrated example of FIG. 25, the second segment 2510 extends from the first segment 2508 towards the second surface 2018 of the PCB 1706. For example, the second segment 2510 is an integral extension of the first segment 2508. In some examples, the second segment 2510 is distinct from and coupled to (e.g., threaded to, adhered to, welded to, etc.) the first segment 2508. In the example of FIG. 25, the second segment 2510 extends from the first segment 2508 and rests on the second surface 2018 of the PCB 1706. In some examples, the second segment 2510 is coupled to the PCB 1706 (e.g., via threads, an adhesive, welding, etc.). In some examples, the first standoff 1716 (e.g., the first segment 2508 and the second segment 2510) is independent of the first mounting plate 1704 and is fixed between the first mounting plate 1704 and the PCB 1706 via compressive forces.

In the illustrated example of FIG. 25, the first segment 2508 and the second segment 2510 are made of metal such as stainless steel, aluminum, and/or brass. In some examples, the first segment 2508 and the second segment 2510 are coated with an electrically insulating material. In the example of FIG. 25, the first standoff 1716 is cylindrical in shape (e.g., has a shape that is defined by a cylinder). In other examples, the first standoff 1716 has a shape other than a cylinder. Also, in the example of FIG. 25, an example distal end 2512 of the second segment 2510 has a chamfered edge. For example, the chamfered edge of the distal end 2512 defines an example exterior perimeter 2514 and an example interior perimeter 2516 of the first standoff 1716.

In the illustrated example of FIG. 25, the chamfered edge of the distal end 2512 defines an example cavity 2518 in the first standoff 1716. In the example of FIG. 25, at least some of the cavity 2518 is positioned towards (e.g., faces) the first component 1902 (and/or solder associated therewith). Also, a retained portion of the first standoff 1716 (e.g., portion of the distal end 2512 defined by the interior perimeter 2516) is positioned away from the first component 1902 (and/or solder associated therewith)

In the illustrated example of FIG. 25, the first segment 2508 has a first cross-sectional shape defining a first area and the distal end 2512 of the second segment 2510 has a second cross-sectional shape defining a second area that is smaller than the first area. In this example, the first area and the second area are the same shape (e.g., a circle) but are different sizes. As such, the distal end 2512 of the first standoff 1716 is spaced apart from the first component 1902 (and/or solder associated therewith) by at least the threshold distance 1904 even if a first example end 2520 of the first standoff 1716 is within the threshold distance 1904 of the first component 1902 (and/or solder associated therewith). For example, the distal end 2512 is spaced apart from the first component 1902 in a direction normal to an exterior surface of the first standoff 1716.

In the illustrated example of FIG. 25, an example distance 2522 between the interior perimeter 2516 and the first component 1902 (and/or solder associated therewith) is greater than or equal to the threshold distance 1904. As such, the first standoff 1716 includes a clearance cutout (e.g., the cavity 2518) that ensures that the first component 1902 (and/or solder associated therewith) is far enough away from the portion of the first standoff 1716 that interfaces with the PCB 1706 to avoid problematic stress concentrations on the PCB 1706. Additionally, the distal end 2512 of the first standoff 1716 is a chamfered edge that distributes stress more evenly along the second surface 2018 of the PCB 1706.

As described above, the first fastener 1710A extends through the first standoff 1716 illustrated in FIG. 25. For example, the first standoff 1716 has an example through hole 2524 (e.g., a mounting hole) extending along an axial length of the first standoff 1716. Also, as illustrated in FIG. 25, the cavity 2518 is spaced apart from the through hole 2524. In the example of FIG. 25, the cavity 2518 is defined by a conical surface that is curved around an axial length of the first standoff 1716 and slanted relative to the axial length of the first standoff 1716. For example, the conical surface defining the cavity 2518 is slanted at thirty degrees with respect to an axial length of the first standoff 1716.

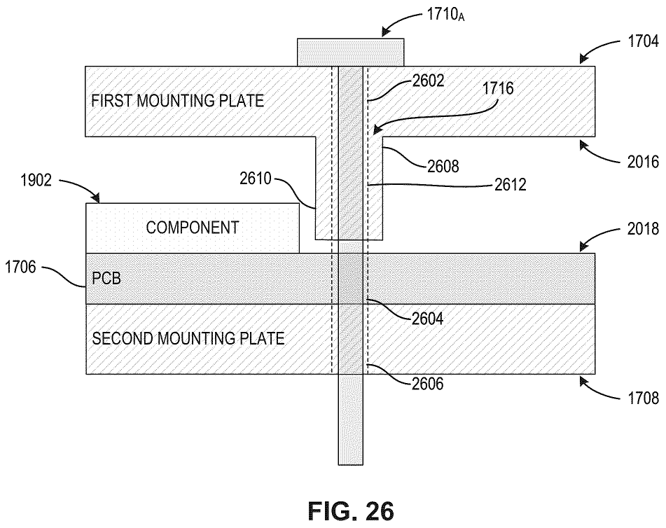

FIG. 26 illustrates a cross-sectional view of a fifth example implementation of the first standoff 1716 of FIG. 17. In the example of FIG. 26, the first fastener 1710A extends through a first example mounting hole 2602 of the first mounting plate 1704, the first standoff 1716, a second example mounting hole 2604 of the PCB 1706, and a third example mounting hole 2606 of the second mounting plate 1708. As such, the first standoff 1716 surrounds (e.g., is to surround) the first fastener 1710A. Also, in the example of FIG. 26, the first standoff 1716 includes a first example end 2608 and a second example end 2610.

In the illustrated example of FIG. 26, the first end 2608 is adjacent to and extends from the first surface 2016 of the first mounting plate 1704 towards the second surface 2018 of the PCB 1706. In some examples, the first standoff 1716 is an integral extension of the first mounting plate 1704 (e.g., a metal plate). In some examples, the first standoff 1716 is distinct from and coupled to (e.g., threaded to, adhered to, welded to, etc.) the first mounting plate 1704. In the example of FIG. 26, the second end 2610 of the first standoff 1716 extends towards the second surface 2018 of the PCB 1706 but does not contact the PCB 1706.

In the illustrated example of FIG. 26, the first end 2608 and the second end 2610 are made of metal such as stainless steel, aluminum, and/or brass. In some examples, the first standoff 1716 is coated with an electrically insulating material. In the example of FIG. 26, the first standoff 1716 is cylindrical in shape (e.g., has a shape that is defined by a cylinder). In other examples, the first standoff 1716 has a shape other than a cylinder. As described above, the first fastener 1710A extends through the first standoff 1716 illustrated in FIG. 26. For example, the first standoff 1716 has an example through hole 2612 (e.g., a mounting hole) extending along an axial length of the first standoff 1716. Advantageously, at least because the first standoff 1716 does not contact the PCB 1706, the first component 1902 (and/or solder associated therewith) is not subjected to stress when the OAM card 1714 is loaded (e.g., by compressive force applied to the first fastener 1710A). In some such examples, the gap between the second end 2610 of the first standoff 1716 and the PCB 1706 is maintained due to other standoffs (e.g., the second standoff 1718 of FIGS. 17 and/or 19) between the first mounting plate 1704 and the PCB 1706 are longer than the first standoff 1716. In some examples, during shock loading, vibration loading, and/or another loading event, the second end 2610 of the first standoff 1716 may come into contact with the second surface 2018 of the PCB 1706. However, the stress on the PCB 1706 produced by the force of such contact will be less than if the first standoff 1716 were constantly in contact with the PCB 1706.

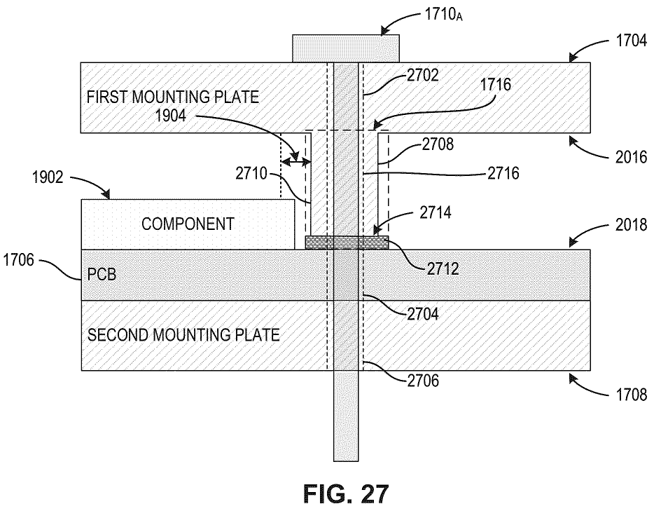

FIG. 27 illustrates a cross-sectional view of a sixth example implementation of the first standoff 1716 of FIG. 17. In the example of FIG. 27, the first fastener 1710A extends through a first example mounting hole 2702 of the first mounting plate 1704, the first standoff 1716, a second example mounting hole 2704 of the PCB 1706, and a third example mounting hole 2706 of the second mounting plate 1708. As such, the first standoff 1716 surrounds (e.g., is to surround) the first fastener 1710A. Also, in the example of FIG. 27, the first standoff 1716 includes a first example segment 2708, a second example segment 2710, and an example compliant structure 2712.

In the illustrated example of FIG. 27, the first segment 2708 is adjacent to and extends from the first surface 2016 of the first mounting plate 1704 towards the second surface 2018 of the PCB 1706. For example, the first segment 2708 is an integral extension of the first mounting plate 1704 (e.g., a metal plate). In some examples, the first segment 2708 is distinct from and coupled to (e.g., threaded to, adhered to, welded to, etc.) the first mounting plate 1704. In the example of FIG. 27, the second segment 2710 extends from the first segment 2708 towards the second surface 2018 of the PCB 1706. For example, the second segment 2710 is an integral extension of the first segment 2708. In some examples, the second segment 2710 is distinct from and coupled to (e.g., threaded to, adhered to, welded to, etc.) the first segment 2708. In the example of FIG. 27, the second segment 2710 extends from the first segment 2708 towards the second surface 2018 of the PCB 1706 but does not contact the PCB 1706.

In the illustrated example of FIG. 27, the first segment 2708 and the second segment 2710 are made of metal such as stainless steel, aluminum, and/or brass. In some examples, the first segment 2708 and the second segment 2710 are coated with an electrically insulating material. In the example of FIG. 27, the first segment 2708 and the second segment 2710 operate as a spacer that is cylindrical in shape (e.g., has a shape that is defined by a cylinder). In other examples, the spacer has a shape other than a cylinder. Also, the spacer (e.g., the first segment 2708 and the second segment 2710) extends a first portion of a length of the first standoff 1716.

In the illustrated example of FIG. 27, the compliant structure 2712 extends a second portion of the length of the first standoff 1716 where the first portion is distinct from the second portion. For example, the compliant structure 2712 is positioned between the spacer (e.g., the first segment 2708 and the second segment 2710) and the second surface 2018 of the PCB 1706. In the example of FIG. 27, the compliant structure 2712 is held in compression between a first example end 2714 of the second segment 2710 and the second surface 2018 of the PCB 1706. For example, the compliant structure 2712 is implemented by a rubber ring that is held in compression between the first end 2714 and the second surface 2018 of the PCB 1706. In additional or alternative examples, the compliant structure 2712 is implemented by at least one of a spring, silicone, foam, or an SMA. In some examples, the compliant structure 2712 is affixed to the first standoff 1716 via an adhesive. In other examples, the compliant structure 2712 is not affixed to the first standoff 1716 but held in place due to compressive forces and/or by the first fastener 1710A.

In the illustrated example of FIG. 27, the compliant structure 2712 is a biasing component that biases the spacer (e.g., the first segment 2708 and the second segment 2710) with respect to the PCB 1706. For example, the compliant structure 2712 exerts a force on at least one of the second segment 2710 or the PCB 1706 to hold the second segment 2710 in a first position relative to the PCB 1706. Additionally or alternatively, the compliant structure 2712 exerts a force on at least one of the second segment 2710 or the PCB 1706 to move the second segment 2710 (e.g., to urge the second segment 2710 to move) relative to the PCB 1706.

As described above, the first fastener 1710A extends through the first standoff 1716 illustrated in FIG. 27. For example, the first standoff 1716 has an example through hole 2716 (e.g., a mounting hole) extending along an axial length of the first standoff 1716. Advantageously, at least because the compliant structure 2712 is positioned between the first end 2714 of the second segment 2710 and the second surface 2018 of the PCB 1706, the first component 1902 (and/or solder associated therewith) is not subjected to sufficient stress to damage the first component 1902 (and/or solder associated therewith) when the OAM card 1714 is loaded (e.g., by compressive force applied to the first fastener 1710A). For example, the compliant structure 2712 cushions (e.g., dampens) the PCB 1706 from movement of the spacer (e.g., the first segment 2708 and the second segment 2710).

Thus, the length of the first standoff 1716 is adjustable (e.g., has an adjustable length) and the compliant structure 2712 allows the first standoff 1716 to absorb stress. For example, when the OAM card 1714 is subjected to loading (e.g., shock loading, vibration loading, thermal cycling, etc.), the spacer (e.g., the first segment 2708 and the second segment 2710) can move as the compliant structure 2712 compresses under the load. In this manner, even though the first component 1902 is within the threshold distance 1904 of the first standoff 1716, the first standoff 1716 prevents localized stress from developing in the first component 1902, solder joints thereof, or the PCB 1706. As such, the first standoff 1716 reduces failure of at least one of the PCB 1706 or the first component 1902 in an area around the first standoff 1716 due to localized stress concentration.

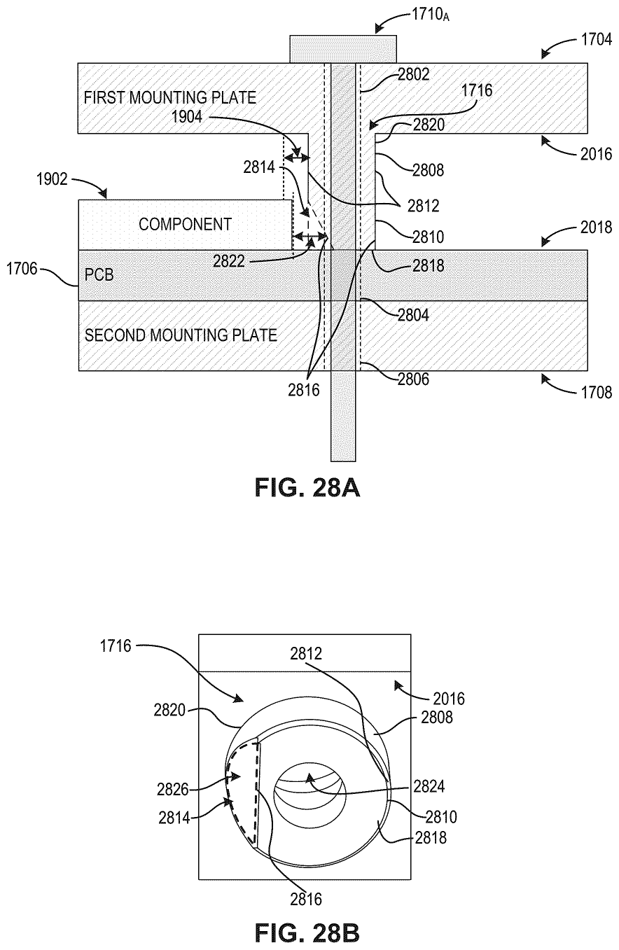

FIG. 28A illustrates a cross-sectional view of a seventh example implementation of the first standoff 1716 of FIG. 17. FIG. 28B illustrates an isometric view of the first standoff 1716 of FIG. 28A. FIGS. 28A and 28B are referred to collectively as FIG. 28. In the example of FIG. 28, the first fastener 1710A extends through a first example mounting hole 2802 of the first mounting plate 1704, the first standoff 1716, a second example mounting hole 2804 of the PCB 1706, and a third example mounting hole 2806 of the second mounting plate 1708. As such, the first standoff 1716 surrounds (e.g., is to surround) the first fastener 1710A. Also, in the example of FIG. 28, the first standoff 1716 includes a first example segment 2808 and a second example segment 2810.

In the illustrated example of FIG. 28, the first segment 2808 is adjacent to and extends from the first surface 2016 of the first mounting plate 1704 towards the second surface 2018 of the PCB 1706. For example, the first segment 2808 is an integral extension of the first mounting plate 1704 (e.g., a metal plate). In some examples, the first segment 2808 is distinct from and coupled to (e.g., threaded to, adhered to, welded to, etc.) the first mounting plate 1704.

In the illustrated example of FIG. 28, the second segment 2810 extends from the first segment 2808 towards the second surface 2018 of the PCB 1706. For example, the second segment 2810 is an integral extension of the first segment 2808. In some examples, the second segment 2810 is distinct from and coupled to (e.g., threaded to, adhered to, welded to, etc.) the first segment 2808. In the example of FIG. 28, the second segment 2810 extends from the first segment 2808 and rests on the second surface 2018 of the PCB 1706. In some examples, the second segment 2810 is coupled to the PCB 1706 (e.g., via threads, an adhesive, welding, etc.). In some examples, the first standoff 1716 (e.g., the first segment 2808 and the second segment 2810) is independent of the first mounting plate 1704 and is fixed between the first mounting plate 1704 and the PCB 1706 via compressive forces.

In the illustrated example of FIG. 28, the first segment 2808 and the second segment 2810 are made of metal such as stainless steel, aluminum, and/or brass. In some examples, the first segment 2808 and the second segment 2810 are coated with an electrically insulating material. In the example of FIG. 28, the first standoff 1716 is cylindrical in shape (e.g., has a shape that is defined by a cylinder) and the first segment 2808 defines an example exterior perimeter 2812 of the first standoff 1716. In other examples, the first standoff 1716 has a shape other than a cylinder. Also, the first standoff 1716 has an example cavity 2814 defining an example inner perimeter 2816 of the first standoff 1716.

In the illustrated example of FIG. 28, the cavity 2814 is positioned towards (e.g., faces) the first component 1902 (and/or solder associated therewith) For example, the cavity 2814 is positioned towards the first component 1902 (and/or solder associated therewith). Also, a retained portion of the first standoff 1716 (e.g., the second segment 2810) is positioned away from the first component 1902 (and/or solder associated therewith).

In the illustrated example of FIG. 28, the first segment 2808 has a first cross-sectional shape defining a first area and the second segment 2810 has a second cross-sectional shape defining a second area that is smaller than the first area. As such, an example distal end 2818 of the first standoff 1716 is spaced apart from the first component 1902 (and/or solder associated therewith) by at least the threshold distance 1904 even if a first example end 2820 of the first standoff 1716 is within the threshold distance 1904 of the first component 1902 (and/or solder associated therewith). For example, the distal end 2818 is spaced apart from the first component 1902 in a direction normal to an exterior surface of the first standoff 1716.

In the illustrated example of FIG. 28, an example distance 2822 between the inner perimeter 2816 and the first component 1902 (and/or solder associated therewith) is greater than or equal to the threshold distance 1904. As such, the first standoff 1716 includes a cut feature (e.g., the cavity 2814) near the first component 1902 that ensures that the first component 1902 (and/or solder associated therewith) is far enough away from the portion of the first standoff 1716 that interfaces with the PCB 1706 to avoid problematic stress concentrations on the PCB 1706. Additionally, the distal end 2818 of the first standoff 1716 is shaped such that stress is distributed away from the first component 1902 (and/or solder associated therewith).

As described above, the first fastener 1710A extends through the first standoff 1716 illustrated in FIG. 28. For example, the first standoff 1716 has an example through hole 2824 (e.g., a mounting hole) extending along an axial length of the first standoff 1716. Also, as illustrated in FIG. 28, the cavity 2814 is spaced apart from the through hole 2824. In other examples, the cavity 2814 may intersect with the through hole 2824. In the example of FIG. 28, the cavity 2814 is defined by an example planar surface 2826 that is angled relative to an axial length of the first standoff 1716. For example, the planar surface 2826 defining the cavity 2814 is angled at thirty degrees with respect to an axial length of the first standoff 1716. In other examples, the planar surface 2826 can be at any other suitable angle.

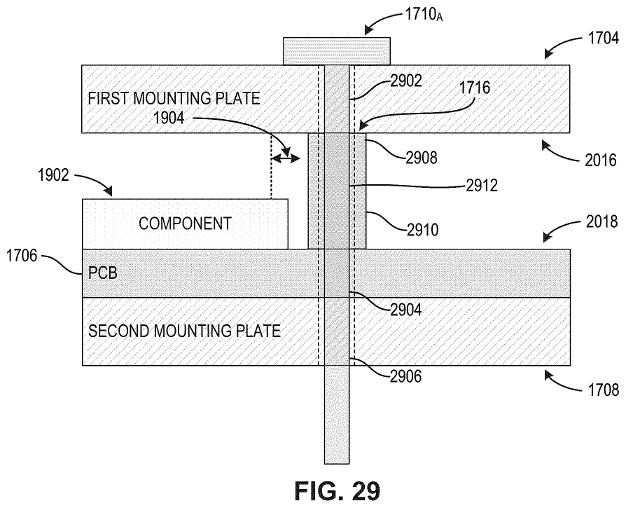

FIG. 29 illustrates a cross-sectional view of an eighth example implementation of the first standoff 1716 of FIG. 17. In the example of FIG. 29, the first fastener 1710A extends through a first example mounting hole 2902 of the first mounting plate 1704, the first standoff 1716, a second example mounting hole 2904 of the PCB 1706, and a third example mounting hole 2906 of the second mounting plate 1708. As such, the first standoff 1716 surrounds (e.g., is to surround) the first fastener 1710A. Also, in the example of FIG. 29, the first standoff 1716 includes a first example end 2908 and a second example end 2910.

In the illustrated example of FIG. 29, the first end 2908 is adjacent to the first surface 2016 and the first standoff 1716 extends from the first surface 2016 of the first mounting plate 1704 towards the second surface 2018 of the PCB 1706. In some examples, the first standoff 1716 is coupled to the first mounting plate 1704 (e.g., via an adhesive, welding, etc.). In some examples, the first standoff 1716 is distinct from and coupled to (e.g., adhered to, welded to, etc.) the first mounting plate 1704. In the example of FIG. 29, the first standoff 1716 extends from the first surface 2016 and rests on the second surface 2018 of the PCB 1706. In some examples, the first standoff 1716 is coupled to the PCB 1706 (e.g., via an adhesive, welding, etc.). In the example of FIG. 29, the first standoff 1716 is fixed between the first mounting plate 1704 and the PCB 1706 via compressive forces.

In the illustrated example of FIG. 29, the first standoff 1716 is made of a compliant structure. For example, the first standoff 1716 is a rubber cylinder with an example through hole 2912. That is, the first standoff 1716 is implemented by at least one piece of rubber that is cylindrical in shape (e.g., has a shape that is defined by a cylinder) with the through hole 2912 extending along an axial length of the first standoff 1716. In additional or alternative examples, the first standoff 1716 is implemented by at least one of a spring, silicone, foam, or an SMA. In some examples, the first standoff 1716 is coated with an electrically insulating material.

In the illustrated example of FIG. 29, the first standoff 1716 is a biasing component that extends a full length of the first standoff 1716 between the first mounting plate 1704 and the PCB 1706. Additionally, the biasing component of the first standoff 1716 biases the first mounting plate 1704 with respect to the PCB 1706. For example, the first standoff 1716 exerts a force on at least one of the first mounting plate 1704 or the PCB 1706 to hold the first mounting plate 1704 in a first position relative to the PCB 1706. Additionally or alternatively, the first standoff 1716 exerts a force on at least one of the first mounting plate 1704 or the PCB 1706 to move the first mounting plate 1704 (e.g., to urge the first mounting plate 1704 to move) relative to the PCB 1706.

As described above, the first fastener 1710A extends through the first standoff 1716 illustrated in FIG. 29. Advantageously, at least because the first standoff 1716 is implemented by a compliant structure (e.g., rubber) and is positioned between the first surface 2016 and the second surface 2018, the first component 1902 (and/or solder associated therewith) is not subjected to sufficient stress to damage the first component 1902 (and/or solder associated therewith) when the OAM card 1714 is loaded (e.g., by a compressive force applied to the first fastener 1710A). For example, the first standoff 1716 cushions the PCB 1706 from movement of the first mounting plate 1704.

Thus, the length of the first standoff 1716 is adjustable (e.g., has an adjustable length) and the compliant structure from which the first standoff 1716 is made allows the first standoff 1716 to absorb stress. For example, when the OAM card 1714 is subjected to loading (e.g., shock loading, vibration loading, thermal cycling, etc.), the first standoff 1716 can move as the compliant structure compresses under the load. In this manner, even though the first component 1902 is within the threshold distance 1904 of the first standoff 1716, the first standoff 1716 prevents localized stress from developing in the first component 1902, solder joints thereof, or the PCB 1706. As such, the first standoff 1716 reduces failure of at least one of the PCB 1706 or the first component 1902 in an area around the first standoff 1716 due to localized stress concentration.

In addition to reducing localized stress concentration in the PCB 1706, examples disclosed herein also improve thermal management in the OAM card 1714. For example, compliant standoffs disclosed herein (e.g., realized with a spring or other compliant structure such as rubber) improve thermal management within the OAM card 1714 by allowing for some degree of independent movement between the PCB 1706 and the first mounting plate 1704. As such, movement between the PCB 1706 and the first mounting plate 1704 stimulates airflow over the PCB 1706 which facilitates heat dissipation.

Additionally, example standoffs implemented by SMAs can aid in thermal management. For example, as described above, the first standoff 1716 can be implemented by SMAs An SMA is an alloy that can define a first shape at a first temperature and can change to define a different second shape when the temperature of the SMA changes to satisfy a temperature threshold. For example, SMAs can be deformed when below the temperature threshold and can return to a pre-deformed (e.g., remembered) shape when heated to or above the temperature threshold. Example SMAs include copper-aluminum-nickel and nickel-titanium as well as SMAs created by alloying zinc, copper, gold, and/or iron.

As such, in examples where the first standoff 1716 is implemented by an SMA, if the PCB 1706 begins to overheat due to Joule heating, the first standoff 1716 aids heat dissipation by transferring heat from the PCB 1706 to the first standoff 1716 which causes the first standoff 1716 to expand (e.g., from a first length to a second length, the second length greater than a third length of the second standoff 1718). Consequently, expansion of the first standoff 1716 raises the first mounting plate 1704 allowing for increased airflow over the PCB 1706 which dissipates heat. Cooling resulting from the dissipated heat causes the first standoff 1716 to contract (e.g., from the second length to the first length, the first length greater than or equal to the third length), returning the first mounting plate 1704 to a native position. The above-described process is automatic and can be realized by SMAs as described above, which acts as a thermo-mechanical switch, driven by thermal loads. For example, no external control is needed as heating and cooling occurs through the use of the OAM card 1714. As such, thermodynamic efficiency of the OAM card 1714 is improved.

Also, for example, one or more independent heaters can be used to control an SMA standoff. For example, in examples where the first standoff 1716 is implemented by an SMA, one or more independent heaters can be switched on (e.g., by a controller, triggered by a temperature condition of the OAM card 1714, etc.) when a mechanical load is applied to the OAM 1700, to cause the first standoff 1716 to contract, thereby reducing the Z-directional form factor (e.g., height, length) of the first standoff 1716. As such, the first standoff 1716 presses against the PCB 1706 with less force (e.g., contracts sufficiently) to cause the first standoff 1716 to become spaced apart from the PCB 1706. As such, contraction of the first standoff 1716 reduces an amount of stress imparted on the PCB 1706 at the location of the first standoff 1716. Thus, the first standoff 1716 reduces stress on the PCB 1706 based on thermal loads from one or more independent heaters.

In examples disclosed herein, by (1) utilizing standoffs such as the first standoff 1716 over areas of a PCB that pose a high risk of localized stress and (2) utilizing standoffs such as the second standoff 1718 over areas of the PCB that pose a low risk of localized stress, examples disclosed herein reduce stress concentration in example OAM cards. Also, utilizing example compliant standoffs aids in absorbing thermal expansion and contraction which mitigates stress transfer to the PCB and components. Additionally, by optimizing the geometry of example standoffs disclosed herein (e.g., by incorporating fillets or chamfers at the part of a standoff that contacts the PCB), examples disclosed herein distribute stress more evenly across the surface of the PCB.

As described above, examples disclosed herein reduce stress concentration. For example, by implementing an example standoff with different cross-sectional shapes at opposite ends of the standoff, localized stress concentration around a mounting hole can be reduced, leading to enhanced structural integrity of a PCB and improved reliability of SMT components. Also, for example, by implementing an example standoff that includes compliant material, localized board strain can be reduced while also maintaining component protection.

Example standoffs disclosed herein reduce stress near component corners (e.g., a high-risk component corner) without significantly changing mounting (e.g., retention) plate design. As such, examples disclosed herein can be implemented without significantly altering the thermal mechanical design of an OAM card. Additionally, examples disclosed herein do not subject other design variables of an OAM card to greater risk. As such, examples disclosed herein can be used to standardize design of OAM cards. For example, disclosed examples establish a standardized design for OAM card retention, which promotes consistency, manufacturability, and ease of implementation across OAM card configurations.

While example manners of implementing the first standoff 1716 of FIG. 17 are illustrated in FIGS. 20-29, one or more of the elements, features, and/or structures illustrated in FIGS. 20-29 may be combined, divided, re-arranged, omitted, eliminated, and/or implemented in any other way. As such, it should be understood that the examples of FIGS. 20-29 are not mutually exclusive but may be used in any combination. For example, any of the cutouts, fillets, and/or chamfers described in connection with FIGS. 23-25 and 28 can be incorporated into the second segment 2010 of FIGS. 20-22. Additionally or alternatively, a compliant structure similar to what is illustrated and described in connection with FIG. 27 can be added to the end of any of the standoffs shown in FIGS. 20-26 and 28. Further still, one or more elements, features, and/or structures of any of the standoffs of FIGS. 20-29 can be implemented by an SMA. As such, example standoffs can change Z-directional form factor (e.g., height, length) based on heat to provide thermal management of an OAM card in addition to dampening motion between mounting plates and PCBs. In some examples, multiple different example standoffs disclosed herein can be used at different locations within a single OAM card. For example, example standoffs disclosed herein can be used over areas of a PCB that pose a high risk of localized stress. Additionally or alternatively, standoffs such as the second standoff 1718 of FIG. 17 can be used over areas of a PCB that pose a low risk of localized stress. As such, examples disclosed herein reduce stress concentration in an OAM card.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects and/or values to recognize the potential presence of variations that occur in real-world applications. For example, “approximately” and “about” may modify dimensions that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified herein

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (1) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that retain a printed circuit board between mounting plates. For example, as described above, areas on a PCB around mounting holes (e.g., the PCB, components thereof, solder joints coupling components to the PCB, etc.) can be subjected to localized stress due to loading on an OAM card. Additionally, areas on a PCB around mounting holes (e.g., the PCB, components thereof, solder joints coupling components to the PCB, etc.) can be subjected to reliability issues due to foreign debris, loose tolerance, board quality, etc. (e.g., due to crowded real estate on a PCB card near a mounting hole).

Advantageously, examples disclosed herein mitigate the problem(s) that may precipitate from the close proximity of components to PCB mounting apertures through a systematic approach. For example, disclosed examples include an array of design features to mitigate the risk of PCB and SMT component failure stemming from (e.g., caused by) localized stress concentrations. One or more example standoffs disclosed herein can be used with a holistic strategy aimed at fortifying thermal mechanical solutions. Examples disclosed herein include OAM card retention techniques and facilitate enhanced durability, reliability, and resilience of OAM cards to stress-induced failures. For example, through the integration of example design features disclosed herein, examples described herein attenuate the phenomenon of stress concentration and safeguard the integrity of OAM card functionality amidst operational conditions. Examples disclosed herein achieve heightened performance and longevity within the purview of OAM infrastructure. Disclosed systems, apparatus, articles of manufacture, and methods improve the efficiency of using a computing device by improving the reliability of accelerator cards to stress. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to retain a printed circuit board between mounting plates are disclosed herein. Further examples and combinations thereof include the following:

Example 1 includes a standoff comprising a first segment to be adjacent to a first surface of a metal plate, a second segment extending from the first segment toward a second surface of a printed circuit board (PCB), the standoff to maintain separation between the metal plate and the PCB, and at least one of a biasing component to dampen motion between the metal plate and the PCB, or a distal end on the second segment, the first segment having a first cross-sectional shape defining a first area, the distal end having a second cross-sectional shape defining a second area, the second area smaller than the first area.

Example 2 includes the standoff of example 1, wherein the first segment is an integral extension of the metal plate.

Example 3 includes the standoff of any of examples 1 or 2, wherein the second segment is an integral extension of the first segment.

Example 4 includes the standoff of any of examples 1 or 2, wherein the second segment is movable relative to the first segment.

Example 5 includes the standoff of any of examples 1, 2, 3, or 4, wherein the standoff includes the biasing component, the biasing component including a spring.

Example 6 includes an apparatus comprising a metal plate, a printed circuit board (PCB) to be coupled to the metal plate, a first standoff to be between the metal plate and a first location on the PCB, the first standoff to apply a first amount of stress at the first location, and a second standoff to be between the metal plate and a second location on the PCB, the second standoff to apply a second amount of stress at the second location, the first amount of stress less than the second amount of stress.

Example 7 includes the apparatus of example 6, wherein the first standoff is aligned with a first opening in the PCB, the second standoff is aligned with a second opening in the PCB, the first opening within a threshold distance of first solder used to mount a first component to the PCB, the second opening more than the threshold distance away from second solder used to mount a second component to the PCB, the threshold distance corresponding to a difference between (a) a first radius of an outermost perimeter of respective ones of the first standoff and the second standoff and (b) a second radius of a perimeter of respective ones of the first opening and the second opening.

Example 8 includes the apparatus of any of examples 6 or 7, wherein the first standoff includes a biasing component, the biasing component to enable the first standoff to vary in length between a first end and a second end, the first end to be adjacent to the metal plate and the second end to be adjacent to the PCB.

Example 9 includes the apparatus of example 8, wherein the first standoff includes a first spacer extending from a first surface of the metal plate toward a second surface of the PCB, and a second spacer extending from the second surface toward the first surface, the second spacer movable relative to the first spacer, the biasing component to urge the second spacer to move relative to the first spacer towards the PCB.

Example 10 includes the apparatus of example 8, wherein the first standoff includes a spacer extending a first portion of a length of the first standoff, and the biasing component extending a second portion of the length of the standoff, the first portion distinct from the second portion.

Example 11 includes the apparatus of example 10, wherein the biasing component is to be positioned between the spacer and the PCB.

Example 12 includes the apparatus of any of examples 8 or 9, wherein the biasing component extends a full length of the standoff between the metal plate and the PCB.

Example 13 includes the apparatus of any of examples 6, 7, 8, 9, 10, or 11, wherein the first standoff includes a first shape at the first end and a second shape at the second end, the first end to be adjacent to a first surface of the metal plate, the second end to be adjacent to a second surface of the PCB, the second shape smaller than the first shape such that the second end is spaced apart from solder on the second surface of the PCB by a threshold distance while the first end is within the threshold distance of the solder in a direction normal to an exterior surface of the first standoff.

Example 14 includes the apparatus of example 13, wherein the first shape is defined by a first cylinder, and the second shape is defined by a second cylinder with a cavity on a side of the second cylinder, the cavity to be positioned towards the solder and a retained portion of the second cylinder to be positioned away from the solder.

Example 15 includes the apparatus of example 14, wherein the first standoff includes a through hole extending along an axial length of the first standoff, the cavity spaced apart from the through hole.

Example 16 includes the apparatus of example 14, wherein the first standoff includes a through hole extending along an axial length of the first standoff, the cavity intersecting the through hole.

Example 17 includes the apparatus of example 14, wherein the cavity is defined by a planar surface that is angled relative to an axial length of the first standoff.

Example 18 includes the apparatus of example 14, wherein the cavity is defined by a planar surface that is approximately parallel to an axial length of the first standoff.

Example 19 includes the apparatus of example 13, wherein the first shape is defined by a first cylinder, and the second shape is defined by a second cylinder with at least one of a chamfered edge or a filleted edge.

Example 20 includes an apparatus comprising a metal plate, a printed circuit board (PCB) to be coupled to the metal plate via threaded fasteners extending through the metal plate and through the PCB, a first standoff to surround a first one of the threaded fasteners, the first standoff to separate the metal plate and the PCB, and a second standoff to surround a second one of the threaded fasteners, the second standoff to separate the metal plate and the PCB, the first standoff at least one of having a different shape than the second standoff or including a different material than the second standoff.

Example 21 includes the apparatus of example 20, wherein the second standoff bas a fixed length, and the first standoff has an adjustable length.

Example 22 includes the apparatus of any of examples 20 or 21, wherein the first standoff includes a shape-memory alloy (SMA), and the SMA is to cause the first standoff to switch between a first length and a second length based on whether a temperature of the first standoff satisfies a temperature threshold, the second length greater than the first length and greater than a third length of the second standoff, the third length less than or equal to the first length.

Example 23 includes the apparatus of any of examples 20, 21, or 22, wherein the PCB has a component mounted to the PCB, and the first standoff includes at least one of (a) a biasing component or (b) a spacer extending from the metal plate toward the PCB, the spacer having a first shape at a first end that is adjacent to a first surface of the metal plate and a second shape at a second end that is adjacent to a second surface of the PCB, the second shape smaller than the first shape such that the second end is at least a threshold distance from the component while the first end is within the threshold distance of the component.

Example 24 includes the apparatus of example 23, wherein the spacer is cylindrical in shape, and has a cavity on a side of the spacer that faces the component, the cavity extending between (a) the PCB and (b) a point between the metal plate and the PCB such that the component is at least the threshold distance from a retained portion at the second end of the spacer, the retained portion having filleted edges.

Example 25 includes the apparatus of example 23, wherein the spacer is cylindrical in shape, extends from the metal plate to the PCB, and has a chamfered edge at the second end such that the component is at least the threshold distance from an inner perimeter of the chamfered edge.

Example 26 includes the apparatus of example 23, wherein the spacer is cylindrical in shape, and has a cavity on a side of the spacer that faces the component, the cavity defined by a planar surface that is angled relative to an axial length of the spacer.

Example 27 includes the apparatus of example 23, wherein the spacer is cylindrical in shape, and has a cavity on a side of the spacer that faces the component, the cavity defined by a planar surface that is approximately parallel to an axial length of the spacer.

Example 28 includes the apparatus of any of examples 23, 24, 25, 26, or 27, wherein the spacer extends from the metal plate toward the PCB and the biasing component is positioned between the spacer and the PCB.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A standoff comprising:
a first segment to be adjacent to a first surface of a metal plate;
a second segment extending from the first segment toward a second surface of a printed circuit board (PCB), the standoff to maintain separation between the metal plate and the PCB; and
at least one of:
a biasing component to dampen motion between the metal plate and the PCB; or
a distal end on the second segment, the first segment having a first cross-sectional shape defining a first area, the distal end having a second cross-sectional shape defining a second area, the second area smaller than the first area.

2. The standoff of claim 1, wherein the first segment is an integral extension of the metal plate.

3. The standoff of claim 1, wherein the second segment is an integral extension of the first segment.

4. The standoff of claim 1, wherein the second segment is movable relative to the first segment.

5. The standoff of claim 1, wherein the standoff includes the biasing component, the biasing component including a spring.

6. An apparatus comprising:
a metal plate;
a printed circuit board (PCB) to be coupled to the metal plate;
a first standoff to be between the metal plate and a first location on the PCB, the first standoff to apply a first amount of stress at the first location; and
a second standoff to be between the metal plate and a second location on the PCB, the second standoff to apply a second amount of stress at the second location, the first amount of stress less than the second amount of stress.

7. The apparatus of claim 6, wherein the first standoff is aligned with a first opening in the PCB, the second standoff is aligned with a second opening in the PCB, the first opening within a threshold distance of first solder used to mount a first component to the PCB, the second opening more than the threshold distance away from second solder used to mount a second component to the PCB, the threshold distance corresponding to a difference between (a) a first radius of an outermost perimeter of respective ones of the first standoff and the second standoff and (b) a second radius of a perimeter of respective ones of the first opening and the second opening.

8. The apparatus of claim 6, wherein the first standoff includes a biasing component, the biasing component to enable the first standoff to vary in length between a first end and a second end, the first end to be adjacent to the metal plate and the second end to be adjacent to the PCB.

9. The apparatus of claim 8, wherein the first standoff includes:
a first spacer extending from a first surface of the metal plate toward a second surface of the PCB; and
a second spacer extending from the second surface toward the first surface, the second spacer movable relative to the first spacer; the biasing component to urge the second spacer to move relative to the first spacer towards the PCB.

10. The apparatus of claim 8, wherein the first standoff includes a spacer extending a first portion of a length of the first standoff, and the biasing component extending a second portion of the length of the standoff, the first portion distinct from the second portion.

11. The apparatus of claim 10, wherein the biasing component is to be positioned between the spacer and the PCB.

12. The apparatus of claim 8, wherein the biasing component extends a full length of the standoff between the metal plate and the PCB.

13. The apparatus of claim 6, wherein the first standoff includes a first shape at the first end and a second shape at the second end, the first end to be adjacent to a first surface of the metal plate, the second end to be adjacent to a second surface of the PCB, the second shape smaller than the first shape such that the second end is spaced apart from solder on the second surface of the PCB by a threshold distance while the first end is within the threshold distance of the solder in a direction normal to an exterior surface of the first standoff.

14. The apparatus of claim 13, wherein the first shape is defined by a first cylinder, and the second shape is defined by a second cylinder with a cavity on a side of the second cylinder, the cavity to be positioned towards the solder and a retained portion of the second cylinder to be positioned away from the solder.

15. The apparatus of claim 14, wherein the first standoff includes a through hole extending along an axial length of the first standoff, the cavity spaced apart from the through hole.

16. The apparatus of claim 14, wherein the first standoff includes a through hole extending along an axial length of the first standoff, the cavity intersecting the through hole.

17. The apparatus of claim 14, wherein the cavity is defined by a planar surface that is angled relative to an axial length of the first standoff.

18. The apparatus of claim 14, wherein the cavity is defined by a planar surface that is approximately parallel to an axial length of the first standoff.

19. The apparatus of claim 13, wherein the first shape is defined by a first cylinder, and the second shape is defined by a second cylinder with at least one of a chamfered edge or a filleted edge.

20. An apparatus comprising:
a metal plate;
a printed circuit board (PCB) to be coupled to the metal plate via threaded fasteners extending through the metal plate and through the PCB;
a first standoff to surround a first one of the threaded fasteners, the first standoff to separate the metal plate and the PCB; and
a second standoff to surround a second one of the threaded fasteners, the second standoff to separate the metal plate and the PCB, the first standoff at least one of having a different shape than the second standoff or including a different material than the second standoff.

21. The apparatus of claim 20, wherein the second standoff has a fixed length, and the first standoff has an adjustable length.

22. The apparatus of claim 20, wherein the first standoff includes a shape-memory alloy (SMA), and the SMA is to cause the first standoff to switch between a first length and a second length based on whether a temperature of the first standoff satisfies a temperature threshold, the second length greater than the first length and greater than a third length of the second standoff, the third length less than or equal to the first length.

23. The apparatus of claim 20, wherein the PCB has a component mounted to the PCB, and the first standoff includes at least one of (a) a biasing component or (b) a spacer extending from the metal plate toward the PCB, the spacer having a first shape at a first end that is adjacent to a first surface of the metal plate and a second shape at a second end that is adjacent to a second surface of the PCB, the second shape smaller than the first shape such that the second end is at least a threshold distance from the component while the first end is within the threshold distance of the component.

24. The apparatus of claim 23, wherein the spacer is cylindrical in shape, and has a cavity on a side of the spacer that faces the component, the cavity extending between (a) the PCB and (b) a point between the metal plate and the PCB such that the component is at least the threshold distance from a retained portion at the second end of the spacer, the retained portion having filleted edges.

25. The apparatus of claim 23, wherein the spacer is cylindrical in shape, extends from the metal plate to the PCB, and has a chamfered edge at the second end such that the component is at least the threshold distance from an inner perimeter of the chamfered edge.

26. The apparatus of claim 23, wherein the spacer is cylindrical in shape, and has a cavity on a side of the spacer that faces the component, the cavity defined by a planar surface that is angled relative to an axial length of the spacer.

27. The apparatus of claim 23, wherein the spacer is cylindrical in shape, and has a cavity on a side of the spacer that faces the component, the cavity defined by a planar surface that is approximately parallel to an axial length of the spacer.

28. The apparatus of claim 23, wherein the spacer extends from the metal plate toward the PCB and the biasing component is positioned between the spacer and the PCB.
